(19) United States
(12) Patent Application Publication
(10) Pub. No.: US 2026/0033037 A1
(43) Pub. Date: Jan. 29, 2026

(54) SINGLE PHOTON DETECTION DEVICE

(71) Applicant: TRUPIXEL INC., Daejeon (KR)

(72) Inventor: Myung-Jae LEE, Daejeon (KR)

(21) Appl. No.: 18/955,267

(22) Filed: Nov. 21, 2024

(30) Foreign Application Priority Data
Jul. 25, 2024 (KR) 10-2024-0099001

(51) Int. Cl. H01L 31/02; H01L 31/107

(52) U.S. Cl. CPC H10F 77/933; H10F 30/225; H10F 77/959

(57) ABSTRACT

A single photon detection device is provided. The single photon detection device comprises a photodetection layer including a first surface and a second surface positioned on opposite sides. The photodetection layer comprises a first well having a first conductivity type, backside patterns positioned between the second surface and the first well, having pitches smaller than a wavelength of light to be detected, a heavily doped region positioned between the first surface and the first well, having a second conductivity type different from the first conductivity type, and a contact region electrically connected to the first well and having the first conductivity type.

### CROSS-REFERENCE TO RELATED APPLICATION

The present application claims priority to and the benefit under 35 U.S.C. § 119 to Korean Patent Application No. 10-2024-0099001, filed on Jul. 25, 2024, in the Korean Intellectual Property Office, the entire disclosure of which is incorporated herein by reference.

### BACKGROUND

The present disclosure relates generally to single photon detection.

Avalanche photodiodes (APDs) are solid-state photodetectors in which a high bias voltage is applied to a p-n junction to provide a high gain from avalanche multiplication. When an incident photon with energy higher than the bandgap of a semiconductor reaches a photodiode, electron-hole pairs (EHPs) are generated. A high electric field rapidly accelerates the photo-generated electrons toward an anode, and the additional electron-hole pairs are subsequently generated by impact ionization of these accelerated electrons, which are then accelerated toward the anode. Similarly, the high electric field rapidly accelerates the photo-generated holes towards a cathode, causing the same phenomenon. This process repeats the process leading to the avalanche multiplication of the photo-generated electrons or holes. Thus, the APDs are semiconductor-based devices that operate similarly to photomultiplier tubes. The linear mode APDs are effective amplifiers that can set the gain by controlling the bias voltage and obtain tens to thousands of the gains in linear mode.

Single-photon avalanche diodes (SPADs) are the APDs in which the p-n junction is biased above the breakdown voltage to operate in geiger mode. A single incident photon can trigger the avalanche phenomenon and generate a very large current, which can easily obtain a measurable pulse with a quenching resistor or circuit. That is, the SPADs operate as devices that generate a large pulse compared to the linear mode APD. After triggering an avalanche, the quenching resistor or circuit is used to reduce the bias voltage below the breakdown voltage to quench the avalanche process. Once the avalanche process is quenched, the bias voltage is increased again above the breakdown voltage so that the SPADs are reset for a detection of another photon.

The SPADs can be configured with the quenching resistors or circuits, recharge circuits, memory, gate circuits, counters, time-to-digital converters, and the like. Since SPAD pixels are semiconductor-based, the SPAD pixels can be easily configured into arrays.

### SUMMARY

One or more example embodiments provide a memory module and electronic device assembly with improved characteristics.

According to some embodiments, a single photon detection device comprises a photodetection layer including a first surface and a second surface positioned on opposite sides. The photodetection layer comprises, a first well having a first conductivity type, backside patterns positioned between the second surface and the first well, having pitches smaller than a wavelength of light to be detected, a heavily doped region positioned between the first surface and the first well, having a second conductivity type different from the first conductivity type, and a contact region electrically connected to the first well and having the first conductivity type.

According to further aspects of the invention, wherein the backside patterns have a width that decreases along a direction from the second surface toward the first surface.

According to further aspects of the invention, the photodetection layer further comprises a substrate region provided between the backside patterns and the first well, the substrate region including a semiconductor material.

According to further aspects of the invention, the substrate region has concave portions into which the backside patterns are inserted, respectively.

According to further aspects of the invention, the photodetection layer further comprises a backside reflection layer provided on the second surface. The backside reflection layer is configured to transmit light incident from the backside reflection layer to the photodetection layer and to reflect light incident from the photodetection layer to the backside reflection layer.

According to further aspects of the invention, the photodetection layer further comprises a side reflection layer provided on a side surface of the first well.

According to further aspects of the invention, the photodetection layer further comprises, a first silicide layer provided on the first surface and covering the heavily doped region, and a second silicide layer provided on the first surface, covering the contact region, and spaced apart from the first silicide layer.

According to further aspects of the invention, the photodetection layer further comprises a guard ring surrounding the heavily doped region between the heavily doped region and the contact region, having the second conductivity type, and having a lower doping concentration than the heavily doped region.

According to further aspects of the invention, the photodetection layer further comprises a second well provided between the heavily doped region and the first well, surrounded by the guard ring, and having the first conductivity type.

According to further aspects of the invention, the photodetection layer further comprises a first silicide layer provided on the first surface and covering the heavily doped region and the guard ring.

According to further aspects of the invention, the photodetection layer further comprises a lightly doped region provided between the first well and the heavily doped region, having the second conductivity type, and having a lower doping concentration than the heavily doped region.

According to further aspects of the invention, the photodetection layer further comprises a guard ring surrounding the lightly doped region between the lightly doped region and the contact region, having the second conductivity type, and having a lower doping concentration than the lightly doped region.

According to further aspects of the invention, the photodetection layer further comprises a device isolation pattern and a vertical isolation pattern sequentially arranged along a direction from the first surface to the second surface, provided adjacent to the first surface on a side surface of the first well.

According to further aspects of the invention, the backside patterns are surrounded by the vertical isolation pattern.

According to further aspects of the invention, the photodetection layer further comprises a side reflection layer extending from a region between the device isolation pattern and the contact region to a region between the vertical isolation pattern and the backside patterns.

According to further aspects of the invention, the photodetection layer comprises a relaxation region provided between the contact region and the first well, having the first conductivity type, and having a lower doping concentration than the contact region.

According to further aspects of the invention, the photodetection layer further comprises an insulation pattern provided between the heavily doped region and the contact region, the insulation pattern including an electrically insulating material.

According to further aspects of the invention, the photodetection layer further comprises a second well provided between the heavily doped region and the first well and having the first conductivity type. The heavily doped region protrudes from a side surface of the second well.

According to further aspects of the invention, the single photon detection device further comprises a connection layer provided on the first surface, the connection layer includes, an output pattern electrically connected to the heavily doped region and configured to reflect light that has passed through the photodetection layer back to the photodetection layer, and a bias pattern electrically connected to the contact region and configured to reflect light that has passed through the photodetection layer back to the photodetection layer.

According to further aspects of the invention, from a planar perspective, the heavily doped region entirely overlaps the output pattern.

Additional aspects will be set forth in part in the description which follows and, in part, will be apparent from the description, or may be learned by practice of some example embodiments of the inventive concepts.

### BRIEF DESCRIPTION OF DRAWINGS

The above and other aspects, features, and advantages of some example embodiments of the present disclosure will be more apparent from the following description taken in conjunction with the accompanying drawings, in which:

FIG. 1 is a plan view of a single photon detection device according to some example embodiments.

FIG. 2 is a cross-sectional view corresponding to line A1-A1′ of FIG. 1 according to some example embodiments.

FIGS. 3A, 3B, 3C, 3D, 3E, and 3F are plan views corresponding to FIG. 1 for explaining exemplary planar shapes of the single photon detection device described with reference to FIG. 2.

FIG. 4 is a plan view of a single photon detection device according to some example embodiments.

FIG. 5 is a cross-sectional view corresponding to line A2-A2′ of the single photon detection device in FIG. 4 according to some example embodiments.

FIGS. 6, 7, 8, 9, 10, 11, 12, 13, 14, and 15 are cross-sectional views corresponding to line B-B′ of FIG. 4 according to some example embodiments.

FIG. 16 is a plan view of a single photon detection device according to some example embodiments.

FIG. 17 is a cross-sectional view corresponding to line A3-A3′ of FIG. 16 according to some example embodiments.

FIG. 18 is a plan view of a single photon detection device according to some example embodiments.

FIG. 19 is a cross-sectional view corresponding to line A4-A4′ of FIG. 18 according to some example embodiments.

FIG. 20 is a plan view of a single photon detection device according to some example embodiments.

FIG. 21 is a cross-sectional view corresponding to line A5-A5′ of FIG. 20 according to some example embodiments.

FIG. 22 is a plan view of a single photon detection device according to some example embodiments.

FIG. 23 is a cross-sectional view corresponding to line A6-A6′ of FIG. 22 according to some example embodiments.

FIG. 24 is a plan view illustrating a frontside of a single photon detection device according to some example embodiments.

FIG. 25 is a plan view illustrating a backside of the single photon detection device of FIG. 24 according to some example embodiments.

FIG. 26 is a cross-sectional view corresponding to line B1-B1′ of FIGS. 24 and 25 according to some example embodiments.

FIG. 27 is a plan view illustrating a backside of a single photon detection device according to some example embodiments.

FIG. 28 is a cross-sectional view corresponding to line B2-B2′ of FIG. 27 according to some example embodiments.

FIG. 29 is a plan view illustrating a frontside of a single photon detection device according to some example embodiments.

FIG. 30 is a plan view illustrating a backside of the single photon detection device of FIG. 29 according to some example embodiments.

FIG. 31 is a cross-sectional view corresponding to line B3-B3′ of FIGS. 29 and 30 according to some example embodiments.

FIGS. 32, 33, 34, 35, 36, 37, 38, 39, 40, 41, 42, and 43 are cross-sectional views corresponding to line B1-B1′ of FIGS. 24 and 25 according to some example embodiments.

FIG. 44 is a plan view illustrating a frontside of a single photon detection device according to some example embodiments.

FIG. 45 is a cross-sectional view corresponding to line B4-B4′ of FIG. 44 according to some example embodiments.

FIG. 46 is a plan view illustrating a frontside of a single photon detection device according to some example embodiments.

FIG. 47 is a cross-sectional view corresponding to line B5-B5′ of FIG. 46 according to some example embodiments.

FIG. 48 is a cross-sectional view corresponding to line B3-B3′ of FIGS. 29 and 30 according to some example embodiments.

FIG. 49 is a plan view illustrating a frontside of a single photon detection device according to some example embodiments.

FIG. 50 is a cross-sectional view corresponding to line B6-B6′ of FIG. 49 according to some example embodiments.

FIG. 51 is a cross-sectional view corresponding to line A2-A2′ of FIG. 4 according to some example embodiments.

FIG. 52 is a cross-sectional view corresponding to line A2-A2′ of FIG. 4 according to some example embodiments, explaining the path of incident light for the single photon detection device of FIG. 51.

FIG. 53 is a cross-sectional view corresponding to line A2-A2′ of FIG. 4 according to some example embodiments.

FIG. 54 is a cross-sectional view corresponding to line A2-A2′ of FIG. 4 according to some example embodiments.

FIG. 55 is a cross-sectional view corresponding to line A2-A2′ of FIG. 4 according to some example embodiments, explaining the path of incident light for the single photon detection device of FIG. 54.

FIG. 56 is a cross-sectional view corresponding to line B1-B1′ of FIGS. 24 and 25 according to some example embodiments.

FIG. 57 is a cross-sectional view corresponding to line B1-B1′ of FIGS. 24 and 25 according to some example embodiments.

FIG. 58 is a plan view of a single photon detection device array according to some example embodiments.

FIG. 59 is a cross-sectional view corresponding to line D-D′ of FIG. 58 according to some example embodiments.

FIGS. 60, 61, and 62 are cross-sectional views corresponding to line D-D′ of FIG. 58 according to some example embodiments.

FIG. 63 is a block diagram for explaining an electronic device according to some example embodiments.

FIGS. 64 and 65 are conceptual diagrams illustrating the application of a LiDAR device to a vehicle according to some example embodiments.

### DETAILED DESCRIPTION

Hereinafter, example embodiments of the present inventive concepts will be described in detail with reference to the accompanying drawings. In the following drawings, the same reference numerals refer to the same components, and the size of each component may be exaggerated in the drawings for clarity and convenience of explanation. Meanwhile, the embodiments described below are merely exemplary and various modifications are possible from the example embodiments.

Hereinafter, when it is described that something is “on” something else, it may include not only being in direct contact but also being indirectly above without contact.

The expression of the singular includes the plural unless the context clearly dictates otherwise. Also, when it is described that a certain part “includes” a certain component, this means, unless there is a description to the contrary, that other components are not excluded but may be further included.

Also, the term “part” used in the specification means a unit that processes at least one function or operation.

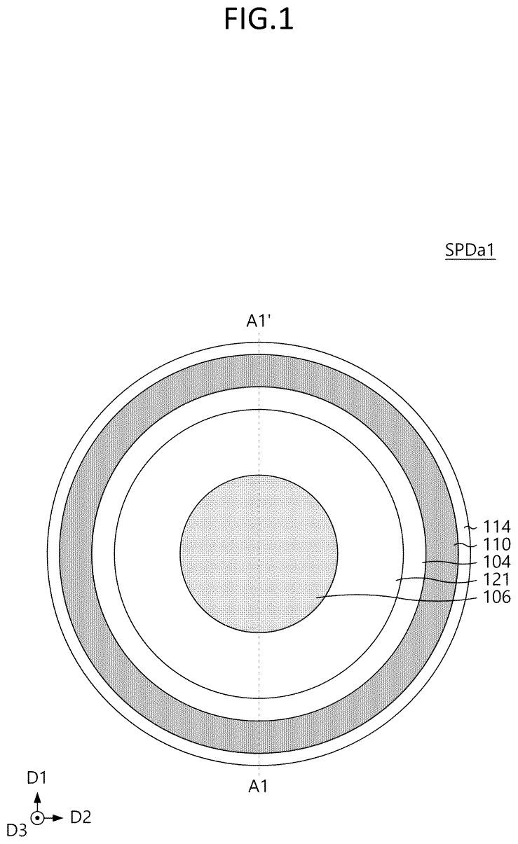

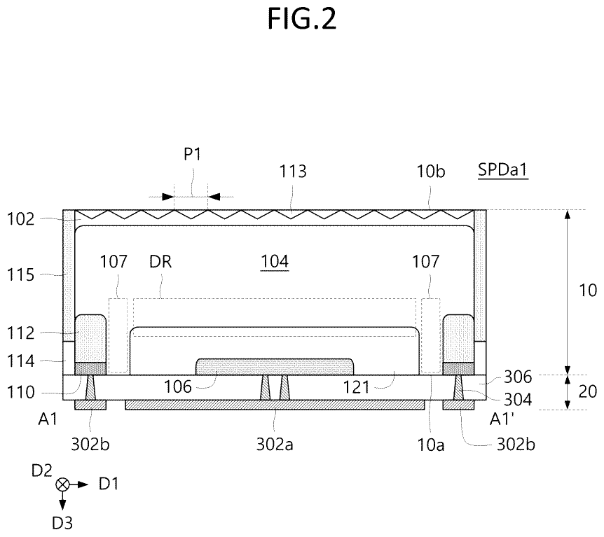

FIG. 1 is a plan view of a single photon detection device according to some example embodiments. FIG. 2 is a cross-sectional view corresponding to line A1-A1′ of FIG. 1 according to some example embodiments.

Referring to FIGS. 1 and 2, a single photon detection device SPDa1 may be provided. The single photon detection device SPDa1 may include a photodetection layer 10 and a connection layer 20. The photodetection layer 10 may include a frontside surface 10a and a backside surface 10b facing each other. The frontside surface 10a may be a surface on which various semiconductor processes are performed during manufacturing of the photodetection layer 10, and the backside surface 10b may be a surface disposed on the opposite side of the frontside surface 10a. The frontside surface 10a and the backside surface 10b may extend along a first direction D1 and a second direction D2. A direction from the backside surface 10b toward the frontside surface 10a may be a third direction D3. The photodetection layer 10 may include a first well 104, a first lightly doped region 121, a heavily doped region 106, a contact region 110, a relaxation region 112, a device isolation pattern 114, a vertical isolation pattern 115, and backside patterns 113 formed on a semiconductor substrate. The heavily doped region 106 on the frontside surface 10a may have a circular shape, and the first lightly doped region 121, the first well 104, the contact region 110, the device isolation pattern 114, and the vertical isolation pattern 115 may have circular ring shapes surrounding the heavily doped region 106. For example, the semiconductor substrate may be a silicon substrate. For example, the first well 104, the first lightly doped region 121, the heavily doped region 106, the contact region 110, and the relaxation region 112 may be formed by implanting impurities into the semiconductor substrate. The remaining region of the semiconductor substrate excluding the first well 104, the first lightly doped region 121, the heavily doped region 106, the contact region 110, and the relaxation region 112 may be referred to as a substrate region 102.

A conductivity type of the substrate region 102 may be n-type or p-type. When the conductivity type of the substrate region 102 is n-type, the substrate region 102 may include impurities of group 5 elements (e.g., phosphorus (P), arsenic (As), antimony (Sb), and the like), group 6 elements, or group 7 elements. Hereinafter, regions having the n-type conductivity may include impurities (hereinafter, first impurities) of group 5, 6, or 7 elements. When the conductivity type of the substrate region 102 is p-type, the substrate region 102 may include impurities of group 3 elements (e.g., boron (B), aluminum (Al), gallium (Ga), indium (In), and the like) or group 2 elements. Hereinafter, regions having the p-type conductivity may include impurities (hereinafter, second impurities) of group 3 or 2 elements. For example, a doping concentration of the substrate region 102 may be 1×10¹⁴˜1×10¹⁹ cm⁻³. The semiconductor substrate may be an epitaxial layer formed by an epitaxial growth process. The surface of the substrate region 102 adjacent to the backside surface 10b (hereinafter, a top surface of the substrate region 102) may have a textured structure including concave portions. In some example embodiments, the concave portions may have a width that decreases along the third direction D3. The shape of the concave portions may be determined as needed. In some example embodiments, the width of the concave portions may increase or remain constant along the third direction D3.

The first well 104 may be provided between the substrate region 102 and the connection layer 20. The first well 104 may directly contact the substrate region 102. The first well 104 may have a first conductivity type. For example, a doping concentration of the first well 104 may be 1×10¹⁵˜1×10¹⁸ cm⁻³. In some example embodiments, the first well 104 may have a uniform doping concentration. In some example embodiments, the doping concentration of the first well 104 may decrease as it approaches the frontside surface 10a. In some example embodiments, a bottom surface of the first well 104 may be positioned at substantially the same height as the frontside surface 10a, this is not limiting. In some other example embodiments, the bottom surface of the first well 104 and the frontside surface 10a may be spaced apart from each other along the third direction D3. A region between the bottom surface of the first well 104 and the frontside surface 10a may be the substrate region 102.

The heavily doped region 106 may be provided between the first well 104 and the connection layer 20. The heavily doped region 106 may have a second conductivity type different from the first conductivity type. When the first conductivity type is n-type or p-type, the second conductivity type may be p-type or n-type, respectively. For example, a doping concentration of the heavily doped region 106 may be 1×10¹⁵˜2×10²⁰ cm⁻³. The heavily doped region 106 may be electrically connected to at least one of an external power supply, a DC-DC converter, and other power management integrated circuits. In some example embodiments, the heavily doped region 106 may be electrically connected to at least one of a quenching resistor (or quenching circuit) and other pixel circuits. The quenching resistor or quenching circuit may stop the avalanche effect and allow the photodetection layer 10 to detect another photon. For example, other pixel circuits may include reset or recharge circuits, memory, amplification circuits, counters, gate circuits, time-to-digital converters, and the like. Other pixel circuits may transmit signals to the photodetection layer 10 or receive signals from the photodetection layer 10.

The first lightly doped region 121 may be provided between the first well 104 and the heavily doped region 106. The first lightly doped region 121 may space apart the heavily doped region 106 and the first well 104. The first lightly doped region 121 may have the second conductivity type different from the first conductivity type. A doping concentration of the first lightly doped region 121 may be lower than the doping concentration of the heavily doped region 106. For example, the doping concentration of the first lightly doped region 121 may be 1×10¹⁶˜1×10¹⁸ cm⁻³.

As the first lightly doped region 121 and the first well 104 have different conductivity types, a depletion region DR may be formed at and around an interface between the first lightly doped region 121 and the first well 104. The depletion region DR may be configured to multiply charges generated in the depletion region DR and charges transferred to the depletion region DR. For example, when the single photon detection device SPDa1 is operated, an electric field of 3×10⁵ V/cm or more may be applied to the depletion region DR. The depletion region DR may be referred to as a multiplication region.

As the doping concentration of the first well 104 decreases as it approaches to the frontside surface 10a, a virtual guard ring 107 may be formed between the first lightly doped region 121 and the relaxation region 112. The virtual guard ring 107 may be a portion of the first well 104 or the substrate region 102. The virtual guard ring 107 may surround the first lightly doped region 121. For example, the virtual guard ring 107 may have a ring shape extending along a region between the first lightly doped region 121 and the relaxation region 112. The virtual guard ring 107 may alleviate a concentration of the electric field on a portion of the depletion region DR, thereby reducing or preventing the premature breakdown phenomenon. The breakdown characteristics of the single photon detection device SPDa1 may be improved by the virtual guard ring 107. The premature breakdown phenomenon refers to the breakdown occurring in the portion of the depletion region DR before a sufficient electric field is applied across the entire depletion region DR, due to the concentration of electric field in the portion of the depletion region DR.

The contact region 110 may be provided on a side surface of the first lightly doped region 121. The contact region 110 may be provided on the opposite side of the first lightly doped region 121 with the virtual guard ring 107 in between. The contact region 110 may be exposed on the frontside surface 10a. The contact region 110 may surround the first lightly doped region 121. In some other example embodiments, the contact region 110 may be provided in a plurality of parts. In this case, the plurality of the contact regions may each be electrically connected to circuits outside the photodetection layer 10. The contact region 110 may have the first conductivity type. A doping concentration of the contact region 110 may be higher than the doping concentration of the first well 104. For example, the doping concentration of the contact region 110 may be 1×10¹⁵˜2×10²¹ cm⁻³. In some example embodiments, the contact region 110 may be electrically connected to at least one of an external power supply, a DC-DC converter, and other power management integrated circuits. In some example embodiments, the contact region 110 may be electrically connected to at least one of a quenching resistor (or quenching circuit) and other pixel circuits.

The relaxation region 112 may be provided on the contact region 110. The relaxation region 112 may be provided between the contact region 110 and the first well 104. The relaxation region 112 may be electrically connected to the contact region 110 and the first well 104. The relaxation region 112 may improve the electrical connection characteristics between the contact region 110 and the first well 104. For example, the relaxation region 112 may be configured to reduce or prevent a voltage drop when a voltage is applied to the first well 104 through the contact region 110, and to allow voltage to be uniformly applied to the first well 104. The relaxation region 112 may extend along the contact region 110. The relaxation region 112 may contact a top surface of the contact region 110. In some other example embodiments, the relaxation region 112 may contact the side and top surfaces of the contact region 110. The first well 104 may extend between the relaxation region 112 and the first lightly doped region 121. The region between the relaxation region 112 and the first lightly doped region 121 may be completely filled with the first well 104. The first well 104 between the relaxation region 112 and the first lightly doped region 121 may be exposed on the frontside surface 10a. The relaxation region 112 may have the first conductivity type. A doping concentration of the relaxation region 112 may be lower than the doping concentration of the contact region 110 and similar to or higher than the doping concentration of the first well 104. For example, the doping concentration of the relaxation region 112 may be 1×10¹⁵˜5×10 cm⁻³.

The backside patterns 113 may be provided in a region adjacent to the backside surface 10b. The backside patterns 113 may fill the concave portions. The backside patterns 113 may be arranged along a direction parallel to the frontside surface 10a. Hereinafter, the direction parallel to the frontside surface 10a may refer to the first direction D1, the second direction D2, or a combined direction of the first direction D1 and the second direction D2. The backside patterns 113 may have first pitches P1. The first pitch P1 may be smaller than the wavelength of the light to be detected. Accordingly, the reflectance of the light to be detected with respect to the photodetection layer 10 may be reduced. In other words, the transmittance of the light to be detected with respect to the photodetection layer 10 may be increased. For example, when the pitch P1 of the backside patterns 113 is approximately 300 nanometers (nm), visible light and near-infrared light with longer wavelengths (e.g., light with a wavelength of approximately 940 nanometers (nm)) reflected from a top surface of the photodetection layer 10 may be reduced. As the transmittance of the light to be detected with respect to the photodetection layer 10 increases, the light detection efficiency of the single photon detection device SPDa1 may be improved.

The device isolation pattern 114 may surround the relaxation region 112. The device isolation pattern 114 may be exposed on the frontside surface 10a. The device isolation pattern 114 may include an electrically insulating material. For example, the device isolation pattern 114 may include silicon oxide (e.g., SiO₂), silicon nitride (e.g., SiN), silicon oxynitride (e.g., SiON), or combinations thereof. For example, the device isolation pattern 114 may be formed by filling a recessed region formed by etching the semiconductor substrate with an electrically insulating material (e.g., silicon oxide). For example, the device isolation pattern 114 may be shallow trench isolation (STI). The device isolation pattern 114 may electrically isolate the photodetection layer 10 and other semiconductor devices (e.g., other photodetection layers 10 or electronic devices constituting other circuits (e.g., transistors)). In some example embodiments, the device isolation pattern 114 may contact the contact region 110 and the relaxation region 112. In some other example embodiments, the device isolation pattern 114 may be spaced apart from the contact region 110 and the relaxation region 112.

The vertical isolation pattern 115 may be provided between the device isolation pattern 114 and the backside surface 10b. For example, the vertical isolation pattern 115 may be full trench isolation (FTI). The vertical isolation pattern 115 may directly contact the device isolation pattern 114 in a region adjacent to the frontside surface 10a. The vertical isolation pattern 115 may be exposed on the backside surface 10b. For example, a top surface of the vertical isolation pattern 115 may be positioned at substantially the same level as the backside surface 10b. The vertical isolation pattern 115 may surround the first well 104. The vertical isolation pattern 115 may be formed by filling a material that prevents crosstalk between adjacent pixels PX into a recessed region formed by etching the substrate region 102. For example, the vertical isolation pattern 115 may include metal (e.g., copper (Cu), aluminum (Al), tungsten (W), titanium (Ti)), polysilicon, high-k dielectric material (e.g., hafnium oxide (HfO₂), zirconium oxide (zirconia, ZrO₂), tantalum oxide (TaO)), or combinations thereof. In some example embodiments, the vertical isolation pattern 115 may contact the device isolation pattern 114. In some other example embodiments, the vertical isolation pattern 115 may be spaced apart from the device isolation pattern 114. In some other example embodiments, the vertical isolation pattern 115 may contact the frontside surface 10a.

The connection layer 20 may be provided on the frontside surface 10a. The connection layer 20 may include an insulation layer 306, an output pattern 302a, a bias pattern 302b, and vertical connection portions 304. For example, the insulation layer 306 may include silicon oxide (e.g., SiO₂), silicon nitride (e.g., SiN), silicon oxynitride (e.g., SiON), or combinations thereof. For example, the vertical connection portions 304 may include contacts or vias.

The output pattern 302a and the bias pattern 302b may be referred to as horizontal connection portions. The output pattern 302a may be electrically connected to the heavily doped region 106 by the vertical connection portions 304. The output pattern 302a may be configured to extract detection signals from the photodetection layer 10. The output pattern 302a may include an electrically conductive material. For example, the output pattern 302a may include copper (Cu), aluminum (Al), tungsten (W), titanium (Ti), titanium nitride (TiN), or combinations thereof. The output pattern 302a and the corresponding circuits may be electrically connected by conductive lines provided therebetween. The output pattern 302a may transmit detection signals extracted from the photodetection layer 10 to the corresponding circuits.

The bias pattern 302b may be electrically connected to the contact region 110 by the vertical connection portions 304. The bias pattern 302b may be configured to apply a bias to the photodetection layer 10. The bias pattern 302b may include an electrically conductive material. For example, the bias pattern 302b may include copper (Cu), aluminum (Al), tungsten (W), titanium (Ti), titanium nitride (TiN), or combinations thereof. The bias pattern 302b and the corresponding circuits may be electrically connected by conductive lines provided therebetween. The bias pattern 302b may be configured to apply a bias provided from the corresponding circuits to the photodetection layer 10.

The output pattern 302a and the bias pattern 302b may serve as a reflective layer. Light that is not absorbed in the photodetection layer 10 may be reflected by the output pattern 302a and the bias pattern 302b to re-enter the photodetection layer 10. Accordingly, the light absorption efficiency of the photodetection layer 10 may be improved.

In some example embodiments, a shield pattern (not illustrated) may be provided between the output pattern 302a and the bias pattern 302b. The shield pattern may electrically shield between the output pattern 302a and the bias pattern 302b. For example, the shield pattern may be configured so that the detection signal extracted by the output pattern 302a is not affected by the bias signal applied to the bias pattern 302b. For example, the shield pattern between the output pattern 302a and the bias pattern 302b may be electrically isolated from the output pattern 302a and the bias pattern 302b. For example, the shield pattern may be spaced apart from the output pattern 302a and the bias pattern 302b.

The backside patterns 113 of the present disclosure may increase the transmittance of incident light with respect to the substrate region 102. Accordingly, a single photon detection device SPDa1 with improved light absorption efficiency may be provided.

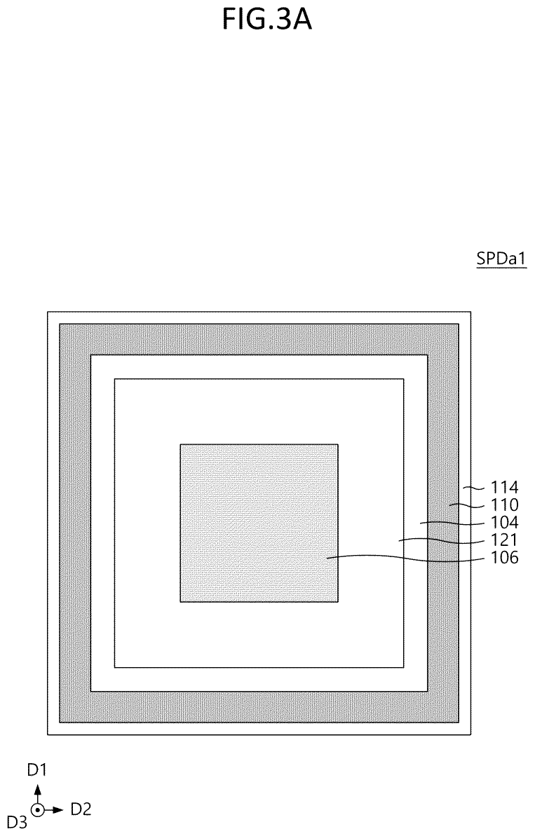

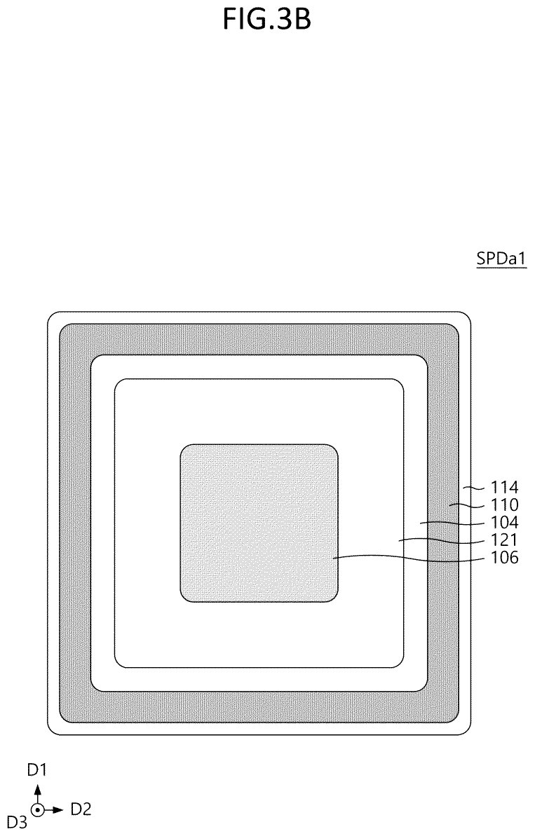

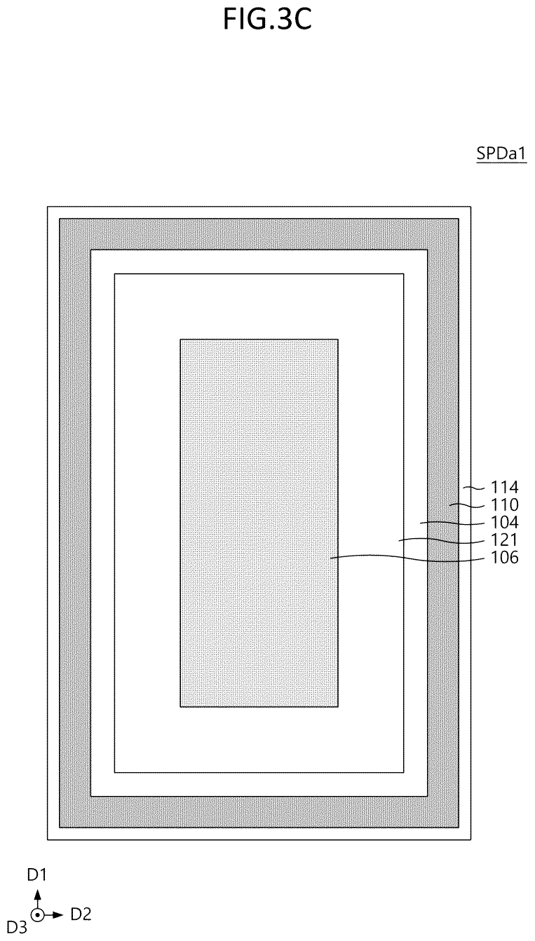

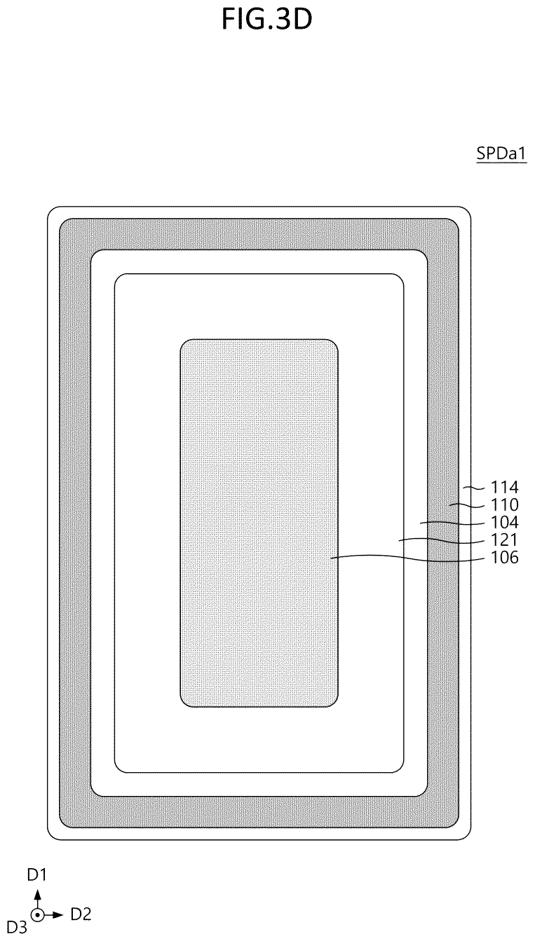

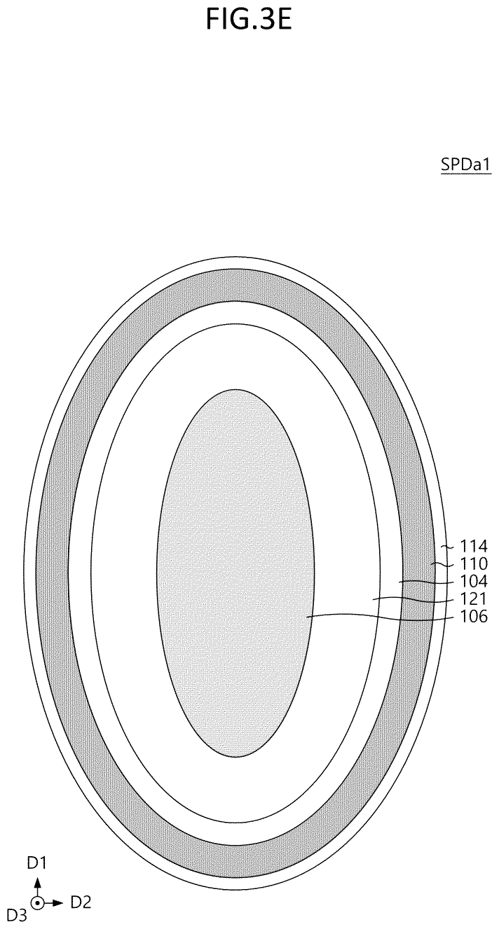

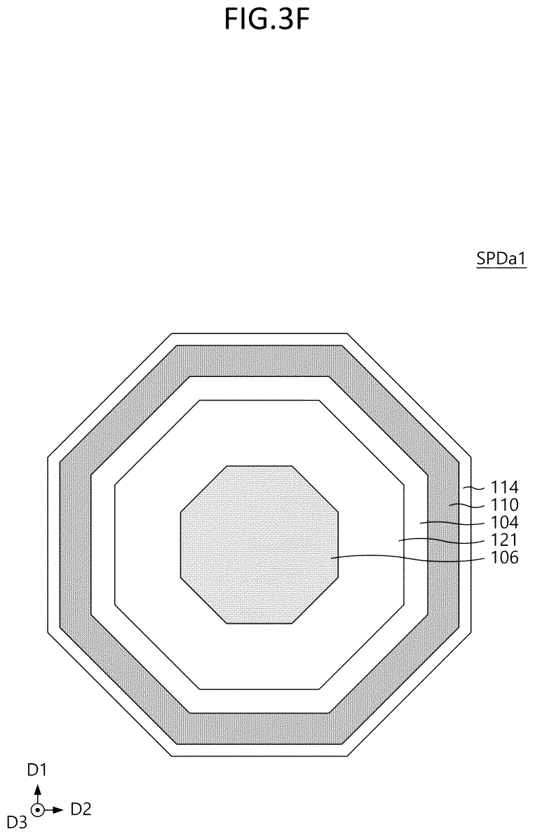

FIGS. 3A to 3F are plan views corresponding to FIG. 1 for explaining exemplary planar shapes of the single photon detection device described with reference to FIG. 2.

Referring to FIGS. 3A to 3F, a single photon detection device SPDa1 may be provided. Unlike some example embodiments, including the example embodiments illustrated in FIG. 1, the heavily doped region 106 may have a square shape, a square shape with rounded corners, a rectangular shape (excluding square shape), a rectangular shape with rounded corners (excluding square shape with rounded corners), an elliptical shape, or an octagonal shape, and the first lightly doped region 121, the first well 104, the contact region 110, and the device isolation pattern 114 may have a square ring shape, a square ring shape with rounded corners, a rectangular ring shape (excluding square ring shape), a rectangular ring shape with rounded corners (excluding square ring shape with rounded corners), an elliptical ring shape, or an octagonal ring shape surrounding the heavily doped region 106. The first lightly doped region 121, the first well 104, the contact region 110, and the device isolation pattern 114 may be sequentially arranged in a direction away from the heavily doped region 106. For example, the first lightly doped region 121, the first well 104, the contact region 110, and the device isolation pattern 114 may have the same center.

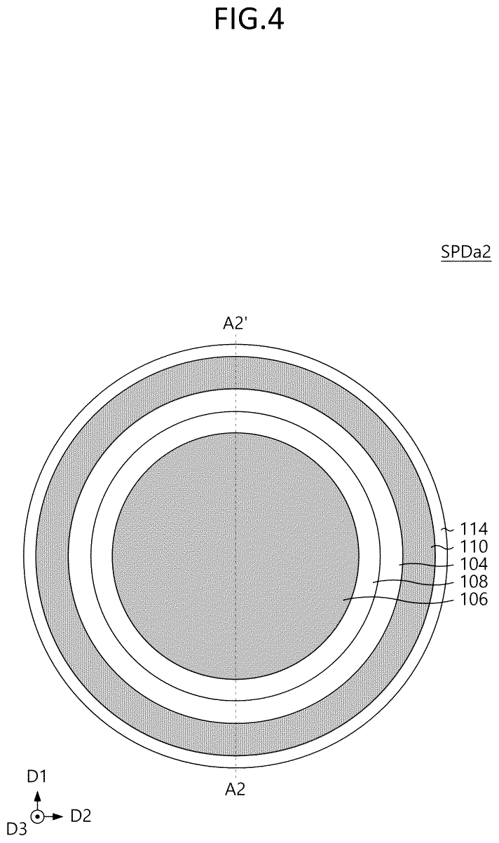

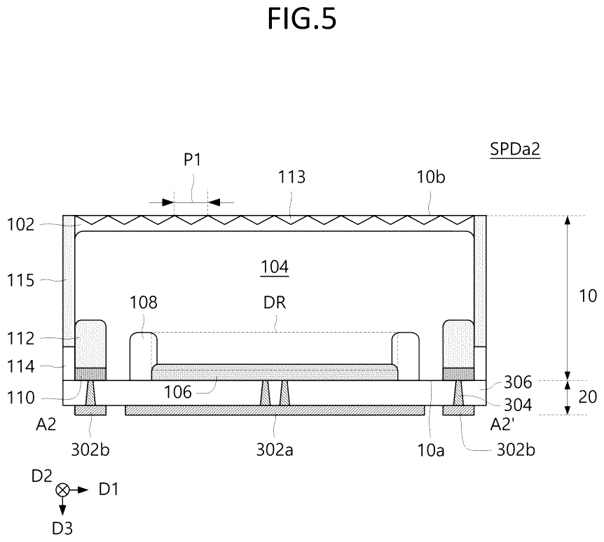

FIG. 4 is a plan view of a single photon detection device according to some example embodiments. FIG. 5 is a cross-sectional view corresponding to line A2-A2′ of the single photon detection device in FIG. 4 according to some example embodiments. For the brevity of explanation, differences from that described with reference to FIGS. 1 to 3 are mainly described.

Referring to FIGS. 4 and 5, a single photon detection device SPDa2 may be provided. Unlike some example embodiments, including the example embodiments illustrated in FIGS. 1 to 3, the single photon detection device SPDa2 may not include the first lightly doped region 121. The depletion region DR may be formed at and around an interface between the heavily doped region 106 and the first well 104.

Unlike some example embodiments, including the example embodiments illustrated in FIGS. 1 to 3, the single photon detection device SPDa2 may include a guard ring 108. The guard ring 108 may surround the heavily doped region 106. The guard ring 108 may be provided on the side of the heavily doped region 106. For example, the guard ring 108 may have a ring shape extending along the side of the heavily doped region 106. The guard ring 108 may directly contact the heavily doped region 106. The guard ring 108 may be configured to surround an edge of the heavily doped region 106. For example, the guard ring 108 may contact the side surface and a top surface of the edge of the heavily doped region 106. In some example embodiments, the guard ring 108 may be spaced apart from the heavily doped region 106. A bottom surface of the guard ring 108 may be positioned at substantially the same level as a bottom surface of the heavily doped region 106. The guard ring 108 may have the second conductivity type. A doping concentration of the guard ring 108 may be lower than the doping concentration of the heavily doped region 106. For example, the doping concentration of the guard ring 108 may be 1×10¹⁵˜1×10¹⁸ cm⁻³. The guard ring 108 may improve the breakdown characteristics of the single photon detection device SPDa2. Specifically, the guard ring 108 may alleviate a concentration of the electric field at the edge of the heavily doped region 106, thereby reducing or preventing the premature breakdown phenomenon. The premature breakdown phenomenon refers to the breakdown occurring at the corner of the heavily doped region 106 before a sufficient electric field is applied to the depletion region, due to the concentration of electric field at the corner of the heavily doped region 106. A depth of the guard ring 108 may be determined as needed. The depth of the guard ring 108 may refer to the distance between the frontside surface 10a and a top surface of the guard ring 108. For example, the guard ring 108 may be formed deeper or shallower than illustrated.

The depletion region DR may be formed in a region surrounded by the guard ring 108. The region surrounded by the guard ring 108 may be a region on an inner side surface of the guard ring 108. The inner side surface of the guard ring 108 may be positioned opposite to an outer side surface of the guard ring 108. The outer side surface of the guard ring 108 may face the relaxation region 112 and the contact region 110.

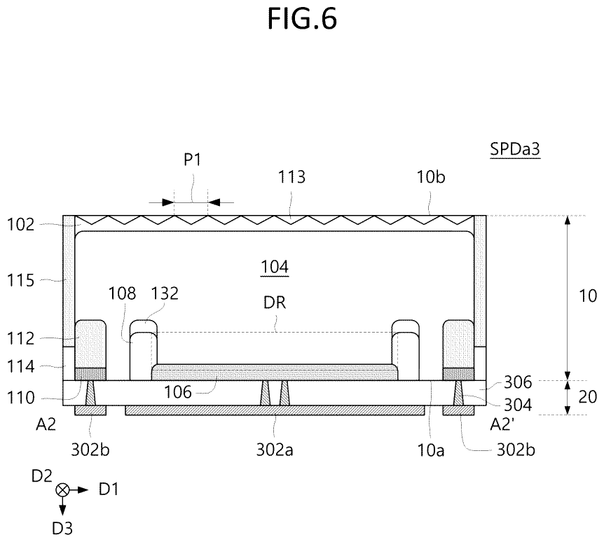

FIGS. 6, 7, 8, 9, 10, 11, 12, 13, 14, and 15 are cross-sectional views corresponding to line B-B′ of FIG. 4 according to some example embodiments. For the brevity of explanation, differences from that described with reference to FIGS. 4 and 5 are described.

Referring to FIG. 6, a single photon detection device SPDa3 may be provided. Unlike some example embodiments, including the example embodiments illustrated in FIGS. 4 and 5, the single photon detection device SPDa3 may include a first additional guard ring 132. The first additional guard ring 132 may be provided on the top surface of the guard ring 108. In some example embodiments, a side surface of the first additional guard ring 132 may be aligned with a side surface of the guard ring 108. For example, the side surface of the first additional guard ring 132 and the side surface of the guard ring 108 may be coplanar. The first additional guard ring 132 may have the same conductivity type as the guard ring 108 and the heavily doped region 106. The first additional guard ring 132 may have the second conductivity type. For example, A doping concentration of the first additional guard ring 132 may be 1×10¹⁵˜1×10¹⁸ cm⁻³. In some example embodiments, the first additional guard ring 132 may have the different doping concentration from that of the guard ring 108. The first additional guard ring 132 may reduce or prevent the occurrence of the premature breakdown phenomenon together with the guard ring 108.

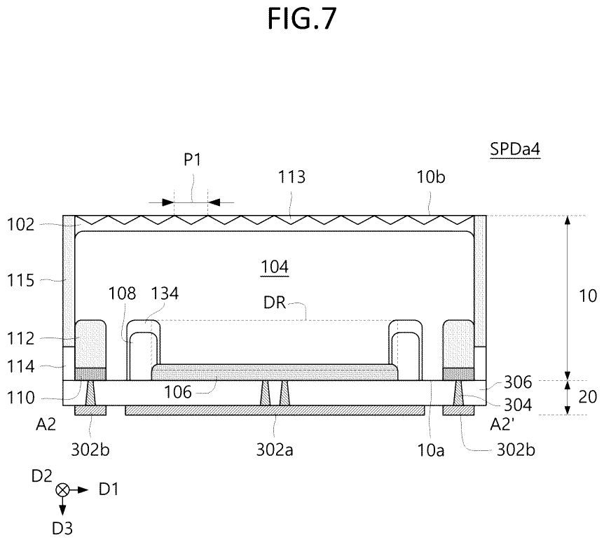

Referring to FIG. 7, a single photon detection device SPDa4 may be provided. Unlike some example embodiments, including the example embodiments illustrated in FIGS. 4 and 5, the single photon detection device SPDa4 may include a second additional guard ring 134. The second additional guard ring 134 may extend from a region on the top surface of the guard ring 108 to the regions on the inner side surface and the outer side surface of the guard ring 108. For example, the second additional guard ring 134 may cover the inner side surface and the outer side surface of the guard ring 108. The guard ring 108 may be spaced apart from the first well 104 by the second additional guard ring 134. The second additional guard ring 134 may have the same conductivity type as the guard ring 108 and the heavily doped region 106. The second additional guard ring 134 may have the second conductivity type. For example, a doping concentration of the second additional guard ring 134 may be 1×10¹⁵˜1×10¹⁸ cm⁻³. In some example embodiments, the second additional guard ring 134 may have the different doping concentration from that of the guard ring 108. The second additional guard ring 134 may reduce or prevent the occurrence of the premature breakdown phenomenon together with the guard ring 108.

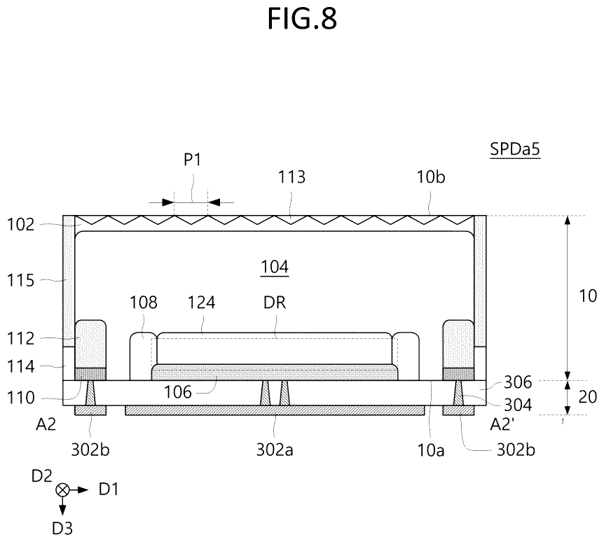

Referring to FIG. 8, a single photon detection device SPDa5 may be provided. Unlike some example embodiments, including the example embodiments illustrated in FIGS. 4 and 5, the single photon detection device SPDa5 may include a second well 124. The second well 124 may be provided between the first well 104 and the heavily doped region 106. The second well 124 may space apart the first well 104 and the heavily doped region 106. For example, the second well 124 may directly contact the first well 104 and the heavily doped region 106. The second well 124 may be provided in an inner region of the guard ring 108 having a ring shape. From the perspective facing the frontside surface 10a, the second well 124 may be surrounded by the guard ring 108. For example, the second well 124 may directly contact the guard ring 108. In some example embodiments, the second well 124 and the guard ring 108 may be formed to substantially the same depth. The depth may refer to the distance from the frontside surface 10a. For example, a top surface of the second well 124 and the top surface of the guard ring 108 may be positioned at substantially the same depth. The second well 124 may have the first conductivity type. For example, a doping concentration of the second well 124 may be 1×10¹⁵˜5×10¹⁷ cm⁻³. In some example embodiments, the second well 124 may have a uniform doping concentration. In some example embodiments, the doping concentration of the second well 124 may decrease as it approaches the heavily doped region 106. However, the distribution of the doping concentration of the second well 124 may be determined as needed. For example, the doping concentration of the second well 124 may increase as it approaches to the heavily doped region 106, or may increase and then decrease as approaches to the heavily doped region 106. The second well 124 may enhance the avalanche effect by increasing the electric field of the depletion region DR. The second well 124 may be configured to improve the characteristics of carriers (i.e., electrons or holes) transferring from the first well 104 to the heavily doped region 106.

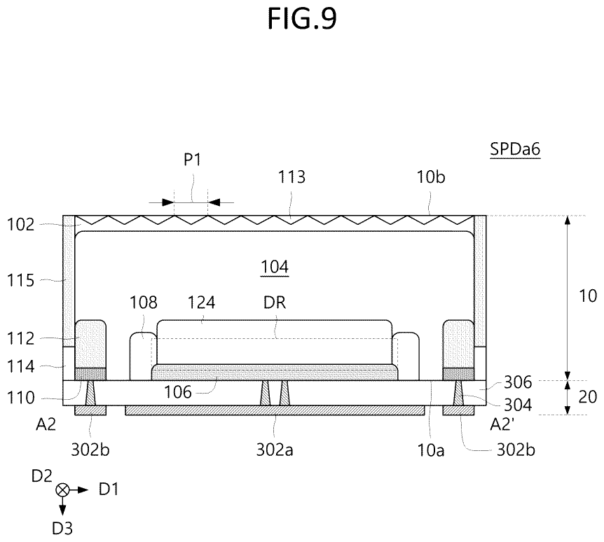

Referring to FIG. 9, a single photon detection device SPDa6 may be provided. Unlike some example embodiments, including the example embodiments illustrated in FIG. 8, the guard ring 108 may extend to a shallower depth than the top surface of the second well 124. The top surface of the guard ring 108 may be positioned at a depth between the top surface and a bottom surface of the second well 124.

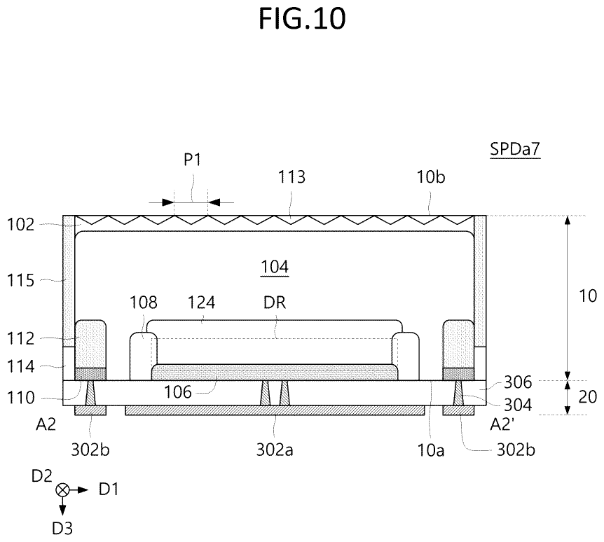

Referring to FIG. 10, a single photon detection device SPDa7 may be provided. Unlike some example embodiments, including the example embodiments illustrated in FIG. 9, the second well 124 may extend from the region on the inner side surface of the guard ring 108 to the region on the top surface of the guard ring 108. For example, the second well 124 may cover an edge portion of the top surface of the guard ring 108. The second well 124 may contact the top surface of the guard ring 108.

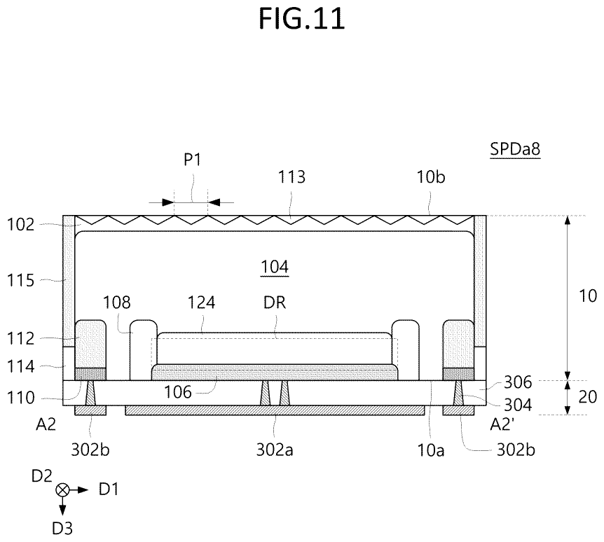

Referring to FIG. 11, a single photon detection device SPDa8 may be provided. Unlike some example embodiments, including the example embodiments illustrated in FIG. 8, the guard ring 108 may extend to a deeper depth than the second well 124. The top surface of the guard ring 108 may be positioned at a depth between the top surface of the second well 124 and a top surface of the first well 104.

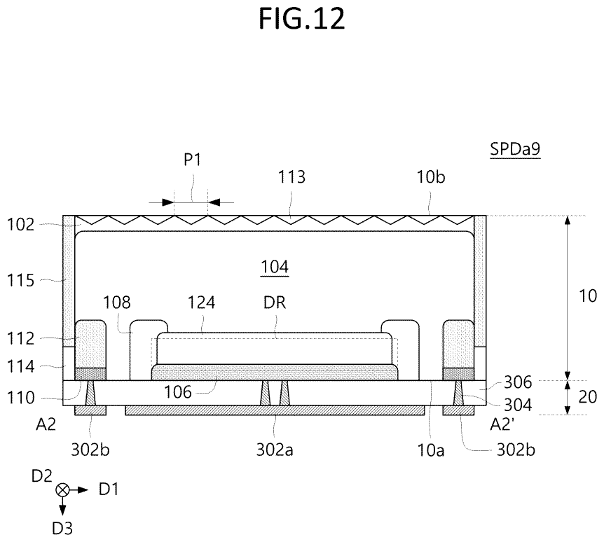

Referring to FIG. 12, a single photon detection device SPDa9 may be provided. Unlike some example embodiments, including the example embodiments illustrated in FIG. 11, the guard ring 108 may extend from a region on a side surface of the second well 124 to a region on the top surface of the second well 124. For example, the guard ring 108 may cover an edge portion of the top surface of the second well 124. The guard ring 108 may contact the top surface of the second well 124.

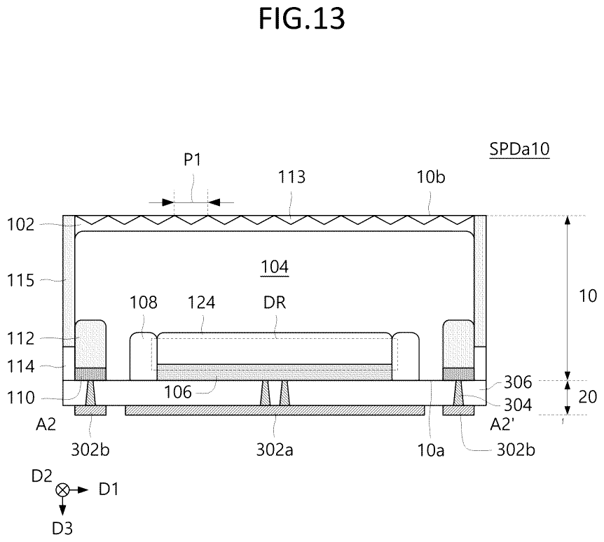

Referring to FIG. 13, a single photon detection device SPDa10 may be provided. Unlike some example embodiments, including the example embodiments illustrated in FIG. 8, the heavily doped region 106 and the second well 124 may have substantially the same width. A side surface of the heavily doped region 106 may be aligned with the side surface of the second well 124. For example, the side surface of the heavily doped region 106 may be coplanar with the side surface of the second well 124.

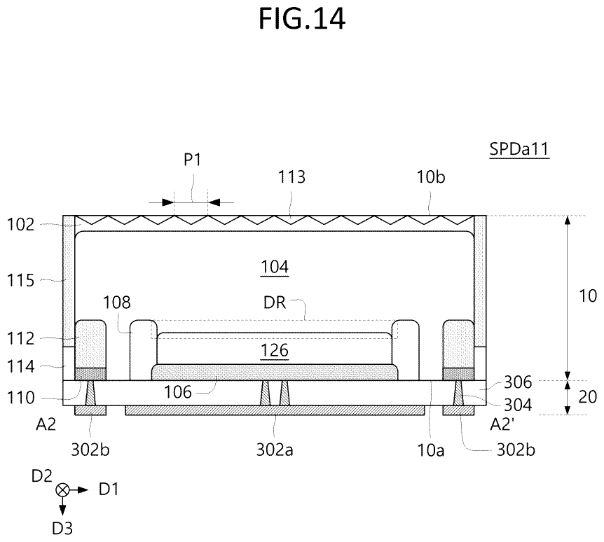

Referring to FIG. 14, a single photon detection device SPDa11 may be provided. Unlike some example embodiments, including the example embodiments illustrated in FIGS. 4 and 5, the single photon detection device SPDa11 may include a third well 126. The third well 126 may be provided between the first well 104 and the heavily doped region 106. The third well 126 may space apart the first well 104 and the heavily doped region 106. For example, the third well 126 may directly contact the first well 104 and the heavily doped region 106. The third well 126 may be provided in the inner region of the guard ring 108 having a ring shape. From the perspective facing the frontside surface 10a, the third well 126 may be surrounded by the guard ring 108. For example, the third well 126 may directly contact the guard ring 108. In some example embodiments, the third well 126 may be formed to a shallower depth than the guard ring 108. A top surface of the third well 126 may be positioned closer to the frontside surface 10a than the top surface of the guard ring 108. The third well 126 may have the second conductivity type. A doping concentration of the third well 126 may be lower than the doping concentration of the heavily doped region 106 and higher than the doping concentration of the guard ring 108. For example, the doping concentration of the third well 126 may be 1×10¹⁵˜5×10¹⁷ cm⁻. The depletion region DR may be formed at and around an interface between the third well 126 and the first well 104. The depletion region DR may be formed widely due to the third well 126.

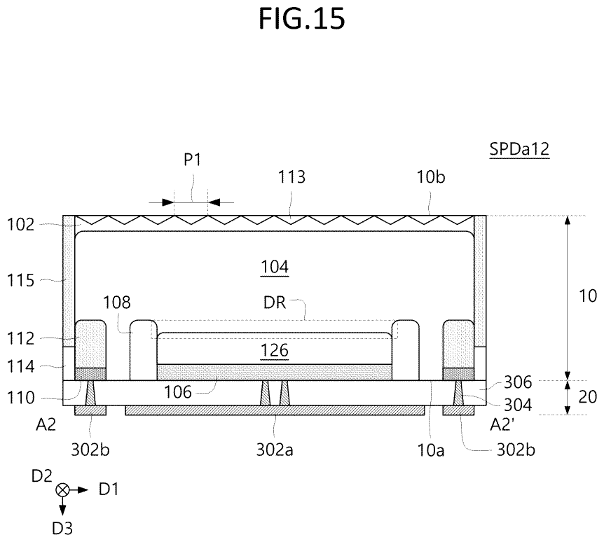

Referring to FIG. 15, a single photon detection device SPDa12 may be provided. Unlike some example embodiments, including the example embodiments illustrated in FIG. 14, the heavily doped region 106 and the third well 126 may have substantially the same width. The side surface of the heavily doped region 106 may be aligned with a side surface of the third well 126. For example, the side surface of the heavily doped region 106 may be coplanar with the side surface of the third well 126.

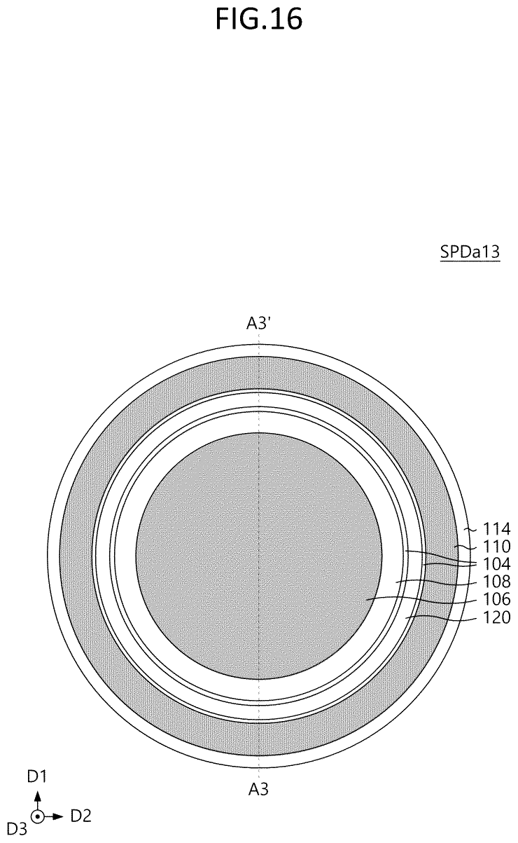

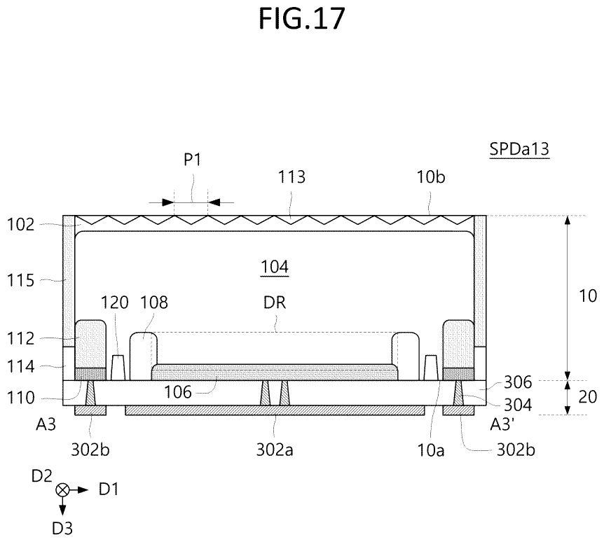

FIG. 16 is a plan view of a single photon detection device according to some example embodiments. FIG. 17 is a cross-sectional view corresponding to line A3-A3′ of FIG. 16 according to some example embodiments. For the brevity of explanation, differences from that described with reference to FIGS. 4 and 5 are described.

Referring to FIGS. 16 and 17, a single photon detection device SPDa13 may be provided. Unlike some example embodiments, including the example embodiments illustrated in FIGS. 4 and 5, the single photon detection device SPDa13 may include a first insulation pattern 120. The first insulation pattern 120 may be provided between the relaxation region 112 and the guard ring 108. In some example embodiments, the first insulation pattern 120 may be spaced apart from the relaxation region 112 and the guard ring 108. In some other example embodiments, the first insulation pattern 120 may directly contact the relaxation region 112 or the guard ring 108. The first insulation pattern 120 may be exposed on the frontside surface 10a. A bottom surface of the first insulation pattern 120 may be exposed between the relaxation region 112 and the guard ring 108. The first insulation pattern 120 may surround the guard ring 108 on the frontside surface 10a. The first insulation pattern 120 may include an electrically insulating material. For example, the first insulation pattern 120 may include silicon oxide (e.g., SiO₂), silicon nitride (e.g., SiN), silicon oxynitride (e.g., SiON), or combinations thereof. For example, the first insulation pattern 120 may be formed by filling an electrically insulating material into a recessed region formed by etching the semiconductor substrate. For example, the first insulation pattern 120 may be STI. The first insulation pattern 120 may be formed in the semiconductor substrate before the first well 104. For example, in the ion implantation process of implanting impurities into the semiconductor substrate to form the first well 104, the first insulation pattern 120 may be configured to reduce the ion implantation effect on a region (i.e., the first well 104) positioned between the second insulation pattern 122 and the backside surface 10b. Compared to the case without the first insulation pattern 120, the doping concentration in a portion of the first well 104 positioned below the first insulation pattern 120 may be decreased with the first insulation pattern 120. Accordingly, the depletion region DR may be formed widely, which may allow the guard ring 108 to function more effectively, and the fill factor and photoelectric conversion efficiency of the single photon detection device SPDa13 may be improved.

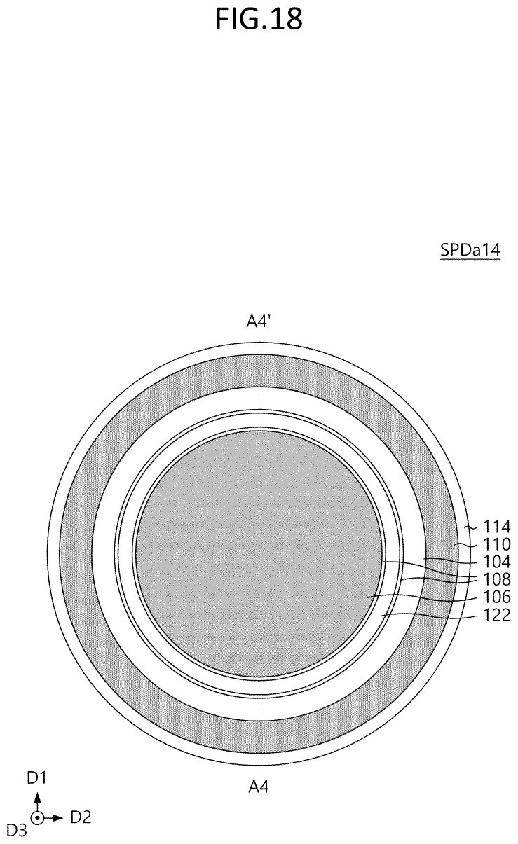

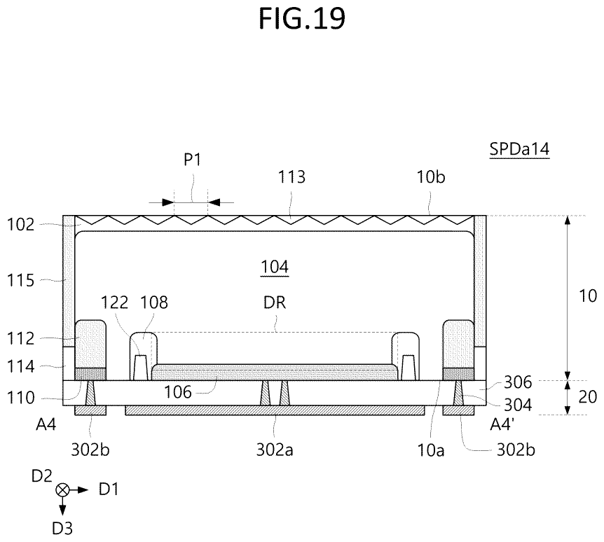

FIG. 18 is a plan view of a single photon detection device according to some example embodiments. FIG. 19 is a cross-sectional view corresponding to line A4-A4′ of FIG. 18 according to some example embodiments. For the brevity of explanation, differences from that described with reference to FIGS. 4 and 5 are described.

Referring to FIGS. 18 and 19, a single photon detection device SPDa14 may be provided. Unlike some example embodiments, including the example embodiments illustrated in FIGS. 4 and 5, the single photon detection device SPDa14 may include a second insulation pattern 122. The second insulation pattern 122 may be provided between the guard ring 108 and the frontside surface 10a. The second insulation pattern 122 may overlap with the guard ring 108 along the third direction D3. The second insulation pattern 122 may surround the heavily doped region 106. For example, the second insulation pattern 122 may have a ring shape extending along the side surface of the heavily doped region 106. In some example embodiments, the second insulation pattern 122 may be spaced apart from the heavily doped region 106. In some other example embodiments, the second insulation pattern 122 may directly contact the heavily doped region 106. The second insulation pattern 122 may be formed from the same level as the bottom surface of the heavily doped region 106 to a certain depth. The depth of the second insulation pattern 122 may be determined as needed. The second insulation pattern 122 may be inserted into the guard ring 108. For example, the side surfaces and top surface of the second insulation pattern 122 may directly contact the guard ring 108. A bottom surface of the second insulation pattern 122 may be exposed to a bottom surface of the semiconductor substrate.

The second insulation pattern 122 may include an electrically insulating material. For example, the second insulation pattern 122 may include silicon oxide (e.g., SiO₂), silicon nitride (e.g., SiN), silicon oxynitride (e.g., SiON), or combinations thereof. In some example embodiments, the second insulation pattern 122 may be STI formed by etching a portion of the semiconductor substrate and then filling the etched region with an electrically insulating material. The second insulation pattern 122 may alleviate a concentration of the electric field on a portion of the depletion region DR, thereby reducing or preventing the premature breakdown phenomenon. The second insulation pattern 122 may reduce or prevent the influence of surface noise components. The second insulation pattern 122 may be formed in the semiconductor substrate before the first well 104 and the guard ring 108. The second insulation pattern 122 may reduce the doping concentration of a region positioned between the second insulation pattern 122 and the backside surface 10b. For example, in the ion implantation process of implanting impurities into the semiconductor substrate to form the first well 104 and the guard ring 108, the second insulation pattern 122 may be configured to lower the ion implantation effect on a region where the first well 104 and the guard ring 108 are formed. Compared to the case without the second insulation pattern 122, the doping concentration of the first well 104 and the guard ring 108 positioned below the second insulation pattern 122 may be decreased with the second insulation pattern 122. Accordingly, the depletion region DR may be formed widely, which may allow the guard ring 108 to function more effectively, and the fill factor and photoelectric conversion efficiency of the single photon detection device SPDa14 may be improved.

In some example embodiments, the single photon detection device SPDa14 may further include the first insulation pattern 120 described with reference to FIGS. 16 and 17.

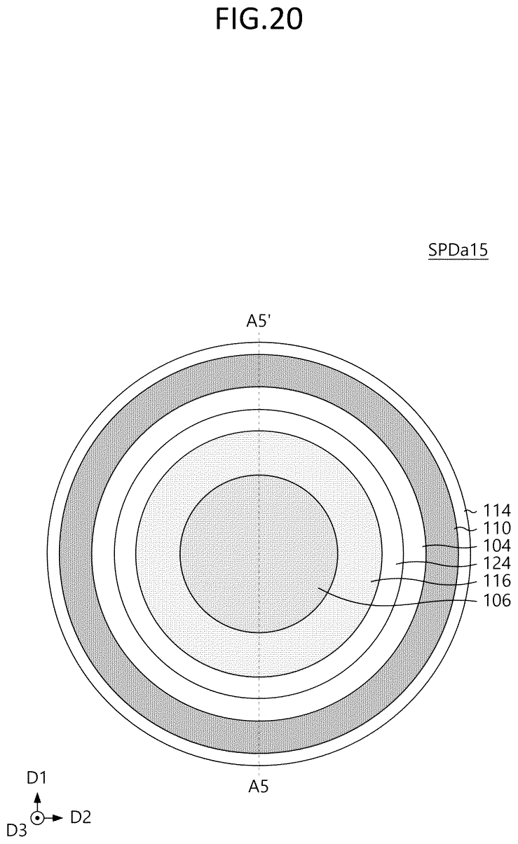

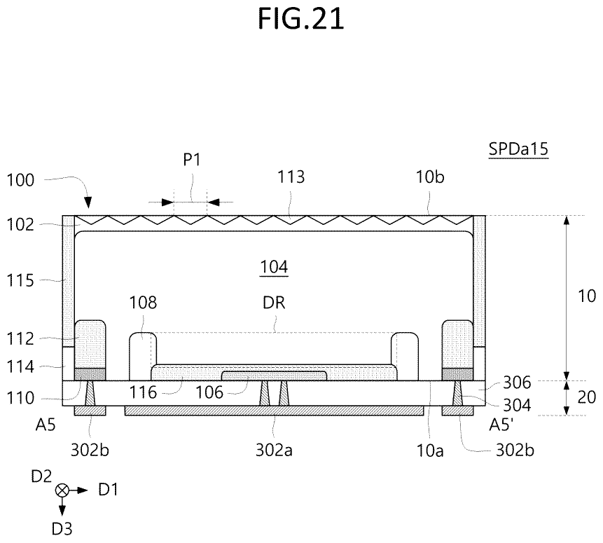

FIG. 20 is a plan view of a single photon detection device according to some example embodiments. FIG. 21 is a cross-sectional view corresponding to line A5-A5′ of FIG. 20 according to some example embodiments. For the brevity of explanation, differences from that described with reference to FIGS. 4 and 5 are described.

Referring to FIGS. 20 and 21, a single photon detection device SPDa15 may be provided. Unlike some example embodiments, including the example embodiments illustrated in FIGS. 4 and 5, the single photon detection device SPDa15 may include a second lightly doped region 116. The second lightly doped region 116 may be provided between the heavily doped region 106 and the first well 104. The second lightly doped region 116 may contact the top surface and side surface of the heavily doped region 106. The second lightly doped region 116 may be exposed on the frontside surface 10a. The second lightly doped region 116 may surround the heavily doped region 106 on the frontside surface 10a. The second lightly doped region 116 may have the second conductivity type. The second lightly doped region 116 may have a lower doping concentration than the heavily doped region 106. For example, the doping concentration of the second lightly doped region 116 may be 1×10¹⁵˜1×10¹⁹ cm³. The second lightly doped region 116 may form the depletion region DR by contacting the first well 104. The second lightly doped region 116 may be configured to reduce or prevent the tunneling effect that occurs as the size of the semiconductor device becomes smaller. For example, the tunneling effect may be current flowing even when no photon has entered the single photon detection device SPDa15. By using the second lightly doped region 116 to form the depletion region DR, the tunneling noise and trap-assisted tunneling noise of the single photon detection device SPDa15 may be reduced, and the operating wavelength range of the single photon detection device SPDa15 may be broadened.

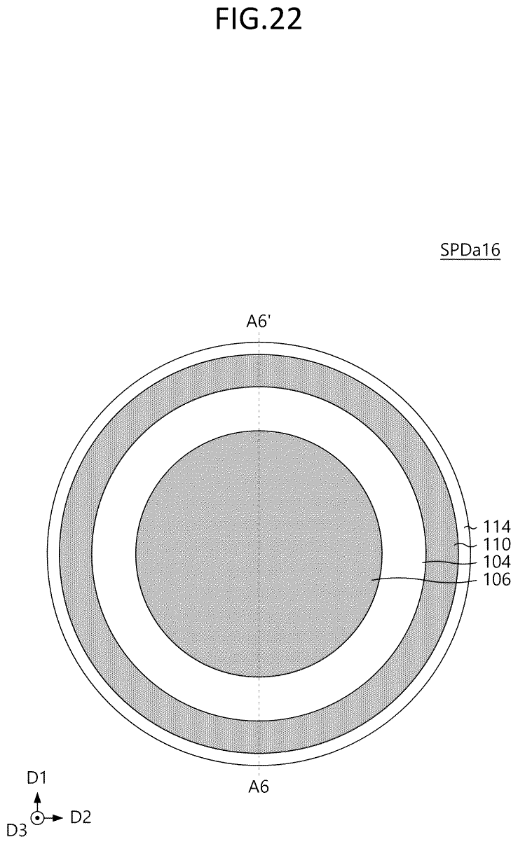

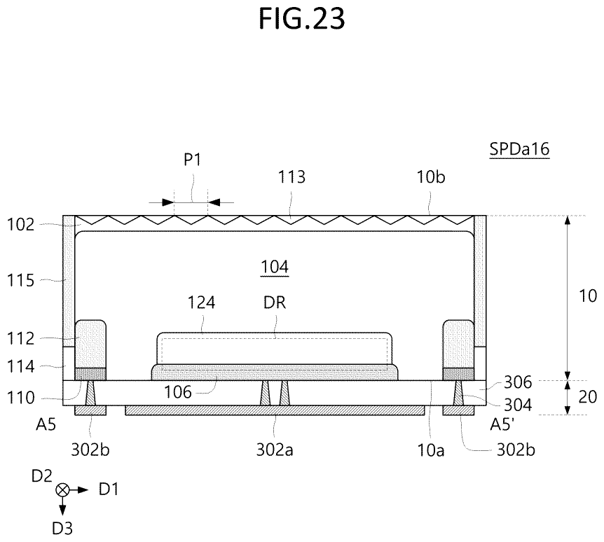

FIG. 22 is a plan view of a single photon detection device according to some example embodiments. FIG. 23 is a cross-sectional view corresponding to line A6-A6′ of FIG. 22 according to some example embodiments. For the brevity of explanation, differences from that described with reference to FIG. 14 are described.

Referring to FIGS. 22 and 23, a single photon detection device SPDa16 may be provided. Unlike some example embodiments, including the example embodiments illustrated in FIG. 14, the single photon detection device SPDa16 may not include the guard ring 108. The heavily doped region 106 and the second well 124 may directly contact the first well 104. A region between the heavily doped region 106, the second well 124, the relaxation region 112, and the contact region 110 may be filled with the first well 104.

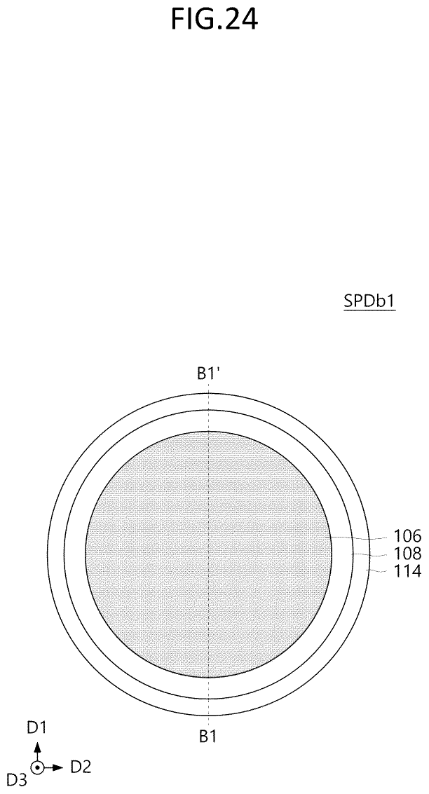

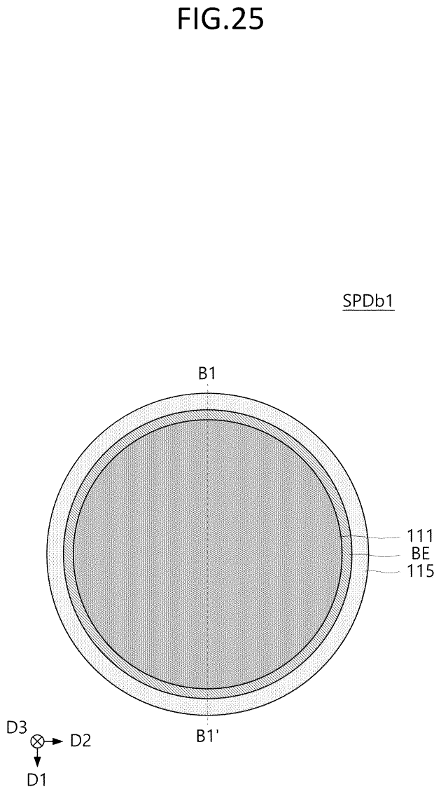

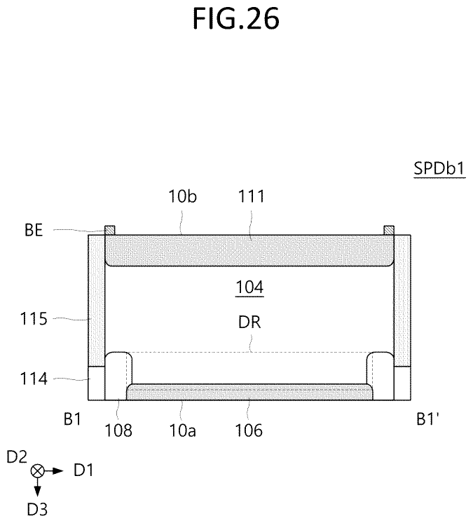

FIG. 24 is a plan view illustrating a frontside of a single photon detection device according to some example embodiments. FIG. 25 is a plan view illustrating a backside of the single photon detection device of FIG. 24 according to some example embodiments. FIG. 26 is a cross-sectional view corresponding to line B1-B1′ of FIGS. 24 and 25 according to some example embodiments. For the brevity of explanation, features that are the same or substantially the same as that described with reference to FIGS. 4 and 5 may not be described.

Referring to FIGS. 24 to 26, a single photon detection device SPDb1 may be provided. The single photon detection device SPDb1 may include a first well 104, a heavily doped region 106, a guard ring 108, a device isolation pattern 114, a vertical isolation pattern 115, a vertical contact region 111, and a back electrode BE. The first well 104, the heavily doped region 106, the guard ring 108, the device isolation pattern 114, and the vertical isolation pattern 115 may be substantially the same as the first well 104, the heavily doped region 106, the guard ring 108, the device isolation pattern 114, and the vertical isolation pattern 115 described with reference to FIGS. 4 and 5, respectively.

The vertical contact region 111 may be provided on the opposite side of the heavily doped region 106 with respect to the first well 104. The vertical contact region 111 may be formed in a region adjacent to the backside surface 10b. The vertical contact region 111 may be provided between the vertical isolation patterns 115. The vertical contact region 111 may contact the vertical isolation patterns 115. For example, from a planar perspective, the vertical contact region 111 may completely fill a region surrounded by the vertical isolation patterns 115. For example, a width of the vertical contact region 111 may be substantially the same as a width of the region surrounded by the vertical isolation patterns 115 (hereinafter, an inner width of the vertical isolation patterns 115). The vertical contact region 111 may overlap with the guard ring 108 and the heavily doped region 106 along the third direction D3. The vertical contact region 111 may have the first conductivity type. A doping concentration of the vertical contact region 111 may be higher than the doping concentration of the first well 104. For example, the doping concentration of the vertical contact region 111 may be 1×10¹⁵˜2×10²⁰ cm⁻³.

The back electrode BE may be provided on the vertical contact region 111. The back electrode BE may be electrically connected to the vertical contact region 111. The back electrode BE may extend along an edge of the vertical contact region 111. The back electrode BE may have a ring shape. The back electrode BE may partially cover the vertical contact region 111. The back electrode BE may expose the vertical contact region 111. In some other example embodiments, the back electrode BE may be provided in a plurality of parts. The back electrode BE may include an electrically conductive material. For example, the back electrode BE may include copper (Cu), aluminum (Al), molybdenum (Mo), platinum (Pt), titanium (Ti), tantalum (Ta), tungsten (W), or combinations thereof. In some example embodiments, the back electrode BE may electrically connect the vertical contact region 111 to at least one of an external power supply, a DC-DC converter, and other power management integrated circuits. In some example embodiments, the back electrode BE may electrically connect the vertical contact region 111 to at least one of a quenching resistor (or quenching circuit) and other pixel circuits.

When the anode and cathode are arranged in the horizontal direction (e.g., the first direction D1 and the second direction D2) of the single photon detection device, the planar size of the single photon detection device may be limited or the fill factor may be difficult to increase, since a region is required to place the anode and cathode from a planar perspective.

In the present disclosure, as the vertical contact region 111 and the heavily doped region 106 are arranged along the vertical direction (i.e., the third direction D3), the anode and cathode of the single photon detection device SPDb1 are arranged in the vertical direction (i.e., the third direction D3). As the anode and cathode are arranged to overlap from a planar perspective, the single photon detection device SPDb1 may be miniaturized or its fill factor can be improved.

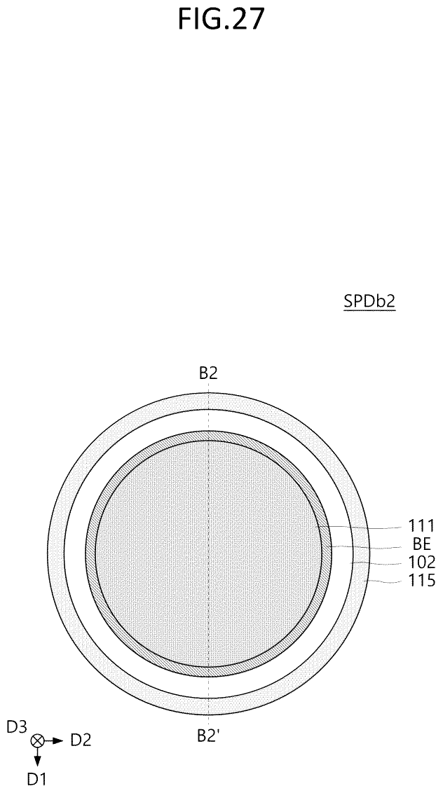

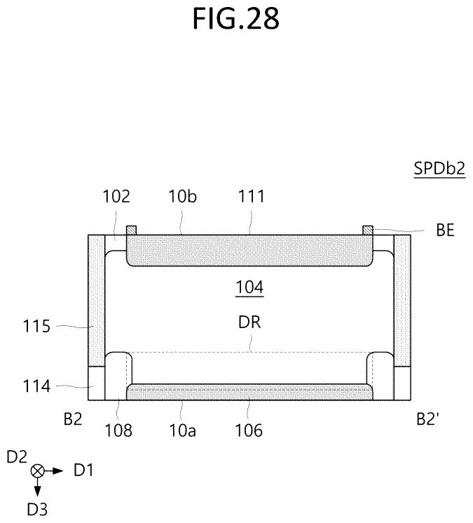

FIG. 27 is a plan view illustrating a backside of a single photon detection device according to some example embodiments. FIG. 28 is a cross-sectional view corresponding to line B2-B2′ of FIG. 27 according to some example embodiments. For the brevity of explanation, differences from that described with reference to FIGS. 24 to 26 are described.

Referring to FIGS. 27 and 28, a single photon detection device SPDb2 may be provided. Unlike some example embodiments, including the example embodiments illustrated in FIGS. 24 to 26, the vertical contact region 111 may be spaced apart from the vertical isolation pattern 115. For example, from a planar perspective, the vertical contact region 111 may partially fill the region surrounded by the vertical isolation pattern 115. For example, the width of the vertical contact region 111 may be smaller than the inner width of the vertical isolation pattern 115. In some example embodiments, the width of the vertical contact region 111 may be substantially the same as a width of the heavily doped region 106.

A substrate region 102 may be provided between the vertical contact region 111 and the vertical isolation pattern 115. The substrate region 102 may be substantially the same as the substrate region 102 described with reference to FIGS. 4 and 5.

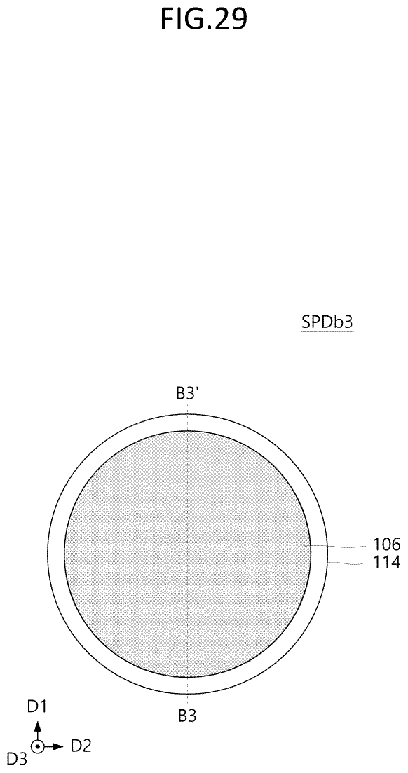

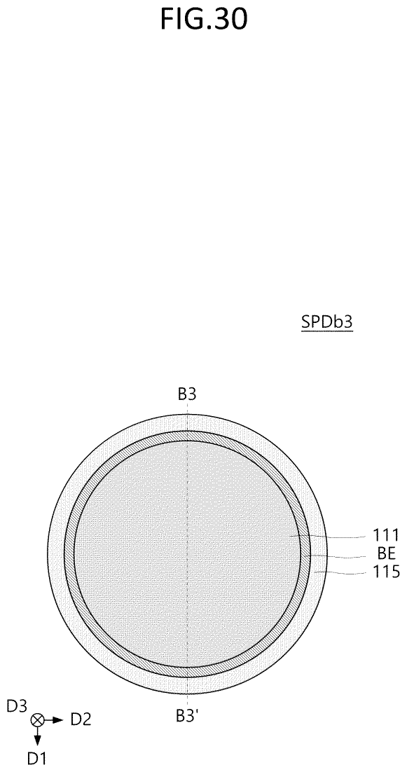

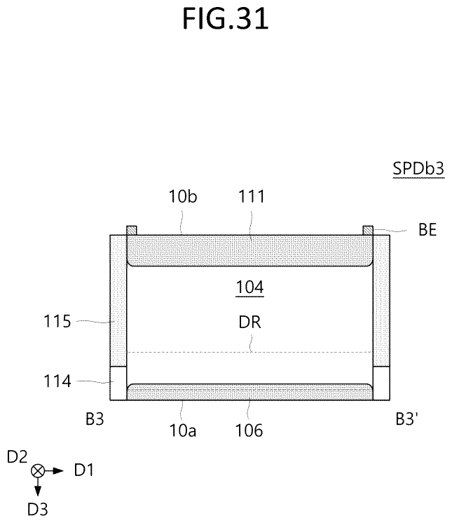

FIG. 29 is a plan view illustrating a frontside of a single photon detection device according to some example embodiments. FIG. 30 is a plan view illustrating a backside of the single photon detection device of FIG. 29 according to some example embodiments. FIG. 31 is a cross-sectional view corresponding to line B3-B3′ of FIGS. 29 and 30 according to some example embodiments. For the brevity of explanation, differences from that described with reference to FIGS. 24 to 26 are described.

Referring to FIGS. 29 to 31, a single photon detection device SPDb3 may be provided. Unlike some example embodiments, including the example embodiments illustrated in FIGS. 24 to 26, the single photon detection device SPDb3 may not include the guard ring 108 of FIG. 26. Accordingly, from a planar perspective, a region for forming the guard ring 108 of FIG. 26 may not be required.

The device isolation pattern 114 may be formed to contact the heavily doped region 106. For example, from a planar perspective, a region surrounded by the device isolation pattern 114 may be completely filled by the heavily doped region 106.

The vertical isolation pattern 115 may be formed to contact the vertical contact region 111. For example, from a planar perspective, the region surrounded by the vertical isolation pattern 115 may be completely filled by the vertical contact region 111.

The present disclosure may provide the single photon detection device SPDb3 with a further reduced planar size by not forming the guard ring.

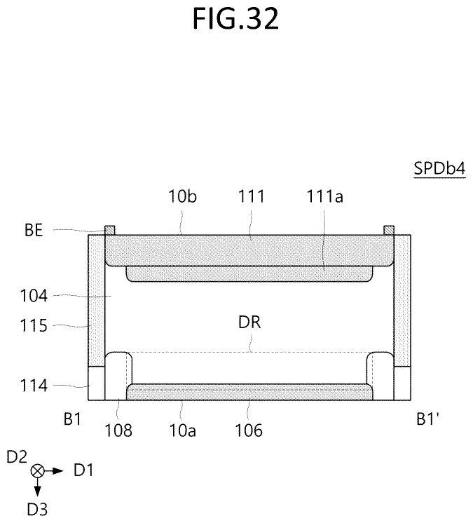

FIGS. 32, 33, 34, 35, 36, 37, 38, 39, 40, 41, 42, and 43 are cross-sectional views corresponding to line B1-B1′ of FIGS. 24 and 25 according to some example embodiments. For the brevity of explanation, differences from that described with reference to FIGS. 24 to 26 are described.

Referring to FIG. 32, a single photon detection device SPDb4 may be provided. Unlike some example embodiments, including the example embodiments illustrated in FIGS. 24 to 26, the single photon detection device SPDb4 may further include an additional contact region 111a. The additional contact region 111a may be provided between the vertical contact region 111 and the first well 104. The additional contact region 111a may contact a bottom surface of the vertical contact region 111. A width of the additional contact region 111a may be smaller than the width of the vertical contact region 111. In some example embodiments, from a planar perspective, a side surface of the additional contact region 111a may be positioned between the outer side surface and the inner side surface of the guard ring 108. For example, the width of the additional contact region 111a may be substantially the same as the width of the heavily doped region 106. A doping concentration of the additional contact region 111a may be higher than the doping concentration of the first well 104. For example, the doping concentration of the additional contact region 111a may be 1×10¹¹˜2×10²¹ cm⁻³.

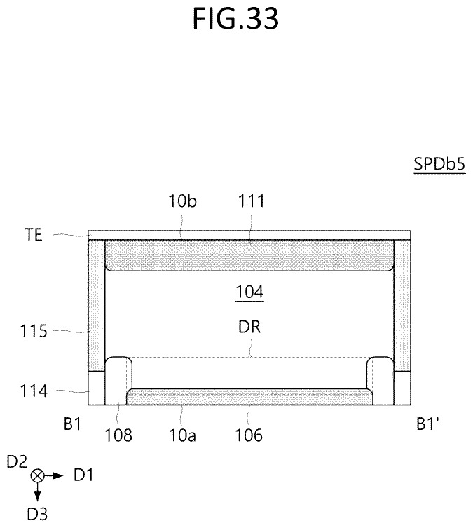

Referring to FIG. 33, a single photon detection device SPDb5 may be provided. Unlike some example embodiments, including the example embodiments illustrated in FIGS. 24 to 26, the single photon detection device SPDb5 may include a transparent electrode TE instead of the back electrode BE. “Transparent” may refer to substantial transparency as well as semi-transparency. The transparent electrode TE may be provided on the backside surface 10b. The transparent electrode TE may extend along the backside surface 10b. The transparent electrode TE may completely cover the vertical contact region 111. The transparent electrode TE may be electrically connected to the vertical contact region 111. The transparent electrode TE may include a transparent conductive material. For example, the transparent electrode TE may include at least one of indium tin oxide (ITO), indium zinc oxide (IZO), zinc oxide (ZnO), indium oxide (In₂O₃), indium gallium oxide (IGO), aluminum-doped zinc oxide (AZO), graphene, carbon nanotubes (CNT), metal mesh, silver nanowires, conductive polymers (e.g., PEDOT.PSS), and radical polymers.

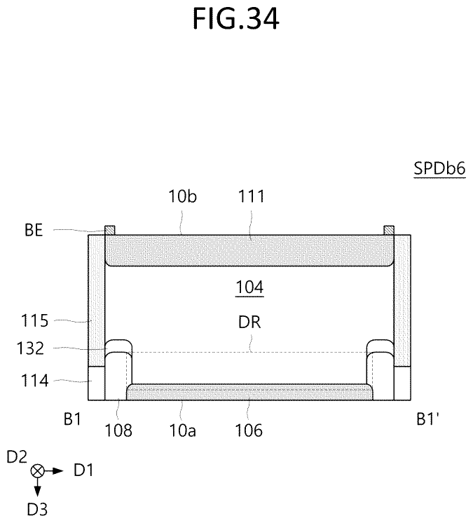

Referring to FIG. 34, a single photon detection device SPDb6 may be provided. Unlike some example embodiments, including the example embodiments illustrated in FIGS. 24 to 26, the single photon detection device SPDb6 may include a first additional guard ring 132. The first additional guard ring 132 may be provided on the top surface of the guard ring 108. In some example embodiments, the side surface of the first additional guard ring 132 may be aligned with the side surface of the guard ring 108. For example, the side surface of the first additional guard ring 132 and the side surface of the guard ring 108 may be coplanar. The first additional guard ring 132 may have the same conductivity type as that of the guard ring 108 and the heavily doped region 106. The first additional guard ring 132 may have the second conductivity type. For example, a doping concentration of the first additional guard ring 132 may be 1×10¹⁵˜1×10¹⁸ cm⁻³. In some example embodiments, the first additional guard ring 132 may have the different doping concentration from that of the guard ring 108. The first additional guard ring 132 may reduce or prevent the occurrence of the premature breakdown phenomenon together with the guard ring 108.

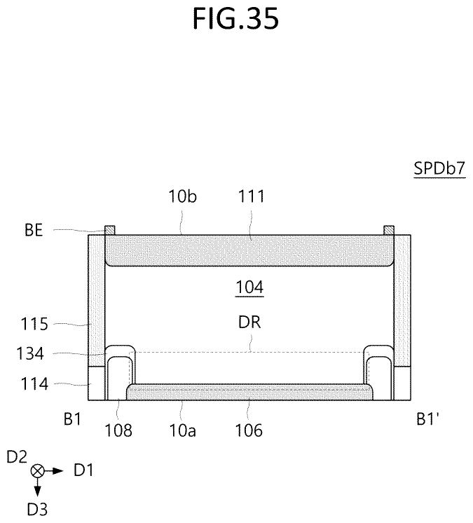

Referring to FIG. 35, a single photon detection device SPDb7 may be provided. Unlike some example embodiments, including the example embodiments illustrated in FIGS. 24 to 26, the single photon detection device SPDb7 may include a second additional guard ring 134. The second additional guard ring 134 may extend from the region on the top surface of the guard ring 108 to the regions on the inner side surface and the outer side surface of the guard ring 108. For example, the second additional guard ring 134 may cover the inner side surface and the outer side surface of the guard ring 108. The guard ring 108 may be spaced apart from the first well 104 by the second additional guard ring 134. The second additional guard ring 134 may have the same conductivity type as that of the guard ring 108 and the heavily doped region 106. The second additional guard ring 134 may have the second conductivity type. For example, a doping concentration of the second additional guard ring 134 may be 1×10¹⁵˜1×10¹⁸ cm⁻³. In some example embodiments, the second additional guard ring 134 may have the different doping concentration from that of the guard ring 108. The second additional guard ring 134 may reduce or prevent the occurrence of the premature breakdown phenomenon together with the guard ring 108.

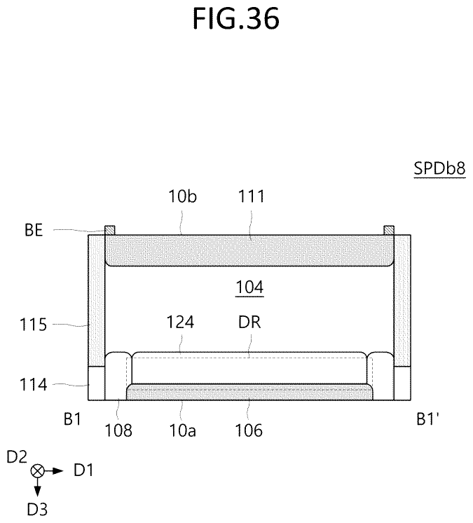

Referring to FIG. 36, a single photon detection device SPDb8 may be provided. Unlike some example embodiments, including the example embodiments illustrated in FIGS. 24 to 26, the single photon detection device SPDb8 may include a second well 124. The second well 124 may be provided between the first well 104 and the heavily doped region 106. The second well 124 may space apart the first well 104 and the heavily doped region 106. For example, the second well 124 may directly contact the first well 104 and the heavily doped region 106. The second well 124 may be provided in the inner region of the guard ring 108 having a ring shape. From the perspective facing the frontside surface 10a, the second well 124 may be surrounded by the guard ring 108. For example, the second well 124 may directly contact the guard ring 108. In some example embodiments, the second well 124 and the guard ring 108 may be formed to substantially the same depth. The depth may refer to the distance from the frontside surface 10a. For example, the top surface of the second well 124 and the top surface of the guard ring 108 may be positioned at substantially the same depth. The second well 124 may have the first conductivity type. For example, a doping concentration of the second well 124 may be 1×10¹⁵˜5×10¹⁷ cm⁻³. In some example embodiments, the second well 124 may have the uniform doping concentration. In some example embodiments, the doping concentration of the second well 124 may decrease as it approaches the heavily doped region 106. However, the distribution of the doping concentration of the second well 124 may be determined as needed. For example, the doping concentration of the second well 124 may increase as it approaches to the heavily doped region 106, or may increase and then decrease as it approaches to the heavily doped region 106. The second well 124 may enhance the avalanche effect by increasing the electric field of the depletion region DR. The second well 124 may be configured to improve the characteristics of carriers (i.e., electrons or holes) transferring from the first well 104 to the heavily doped region 106.

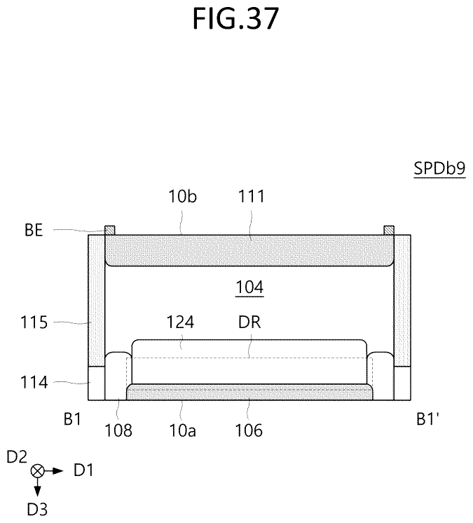

Referring to FIG. 37, a single photon detection device SPDb9 may be provided. Unlike some example embodiments, including the example embodiments illustrated in FIG. 36, the guard ring 108 may extend to a shallower depth than the top surface of the second well 124. The top surface of the guard ring 108 may be positioned at a depth between the top surface and the bottom surface of the second well 124.

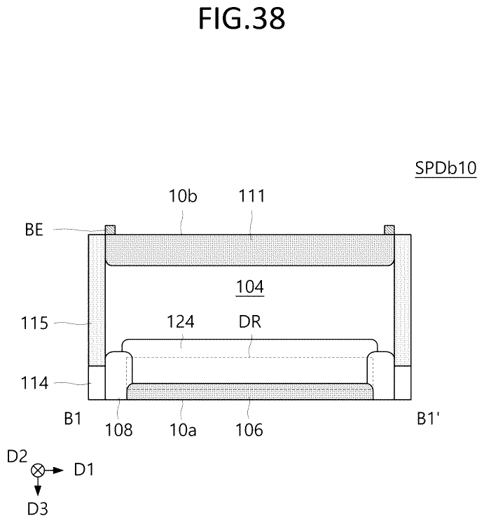

Referring to FIG. 38, a single photon detection device SPDb10 may be provided. Unlike some example embodiments, including the example embodiments illustrated in FIG. 37, the second well 124 may extend from the region on the inner side surface of the guard ring 108 to the region on the top surface of the guard ring 108. For example, the second well 124 may cover the edge portion of the top surface of the guard ring 108. The second well 124 may contact the top surface of the guard ring 108.

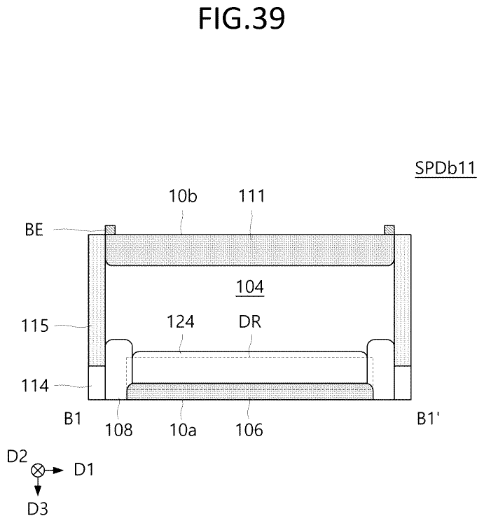

Referring to FIG. 39, a single photon detection device SPDb11 may be provided. Unlike some example embodiments, including the example embodiments illustrated in FIG. 36, the guard ring 108 may extend to a deeper depth than the second well 124. The top surface of the guard ring 108 may be positioned at a depth between the top surface of the second well 124 and the top surface of the first well 104.

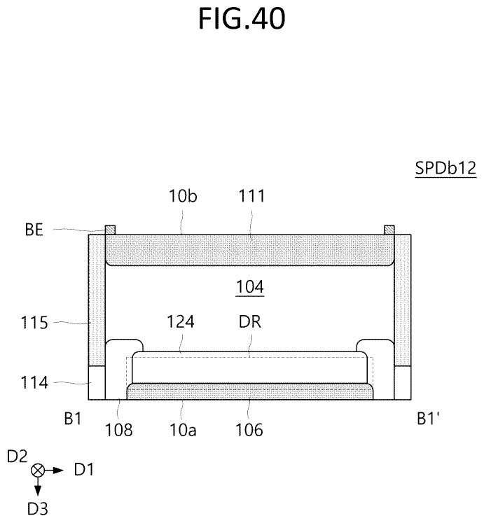

Referring to FIG. 40, a single photon detection device SPDb12 may be provided. Unlike some example embodiments, including the example embodiments illustrated in FIG. 39, the guard ring 108 may extend from the region on the side surface of the second well 124 to the region on the top surface of the second well 124. For example, the guard ring 108 may cover the edge portion of the top surface of the second well 124. The guard ring 108 may contact the top surface of the second well 124.

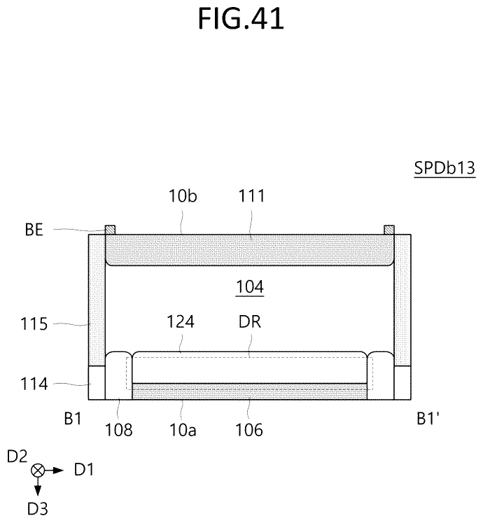

Referring to FIG. 41, a single photon detection device SPDb13 may be provided. Unlike some example embodiments, including the example embodiments illustrated in FIG. 36, the heavily doped region 106 and the second well 124 may have substantially the same width. The side surface of the heavily doped region 106 may be aligned with the side surface of the second well 124. For example, the side surface of the heavily doped region 106 may be coplanar with the side surface of the second well 124.

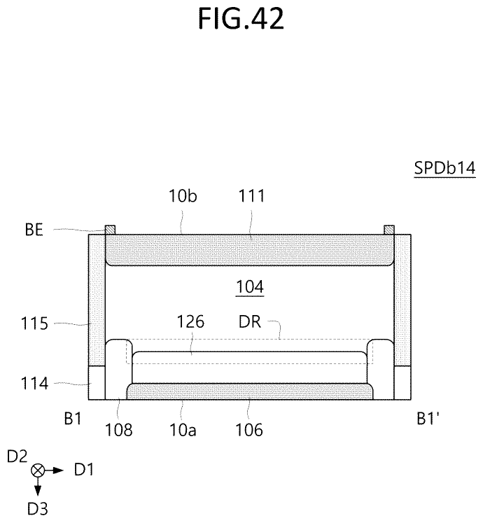

Referring to FIG. 42, a single photon detection device SPDb14 may be provided. Unlike some example embodiments, including the example embodiments illustrated in FIGS. 24 to 26, the single photon detection device SPDb14 may include a third well 126. The third well 126 may be provided between the first well 104 and the heavily doped region 106. The third well 126 may space apart the first well 104 and the heavily doped region 106. For example, the third well 126 may directly contact the first well 104 and the heavily doped region 106. The third well 126 may be provided in the inner region of the guard ring 108 having a ring shape. From the perspective facing the frontside surface 10a, the third well 126 may be surrounded by the guard ring 108. For example, the third well 126 may directly contact the guard ring 108. In some example embodiments, the third well 126 may be formed to a shallower depth than the guard ring 108. The top surface of the third well 126 may be positioned closer to the frontside surface 10a than the top surface of the guard ring 108. The third well 126 may have the second conductivity type. A doping concentration of the third well 126 may be lower than the doping concentration of the heavily doped region 106 and higher than the doping concentration of the guard ring 108. For example, the doping concentration of the third well 126 may be 1×10¹⁵˜5×10¹⁷ cm⁻³. The depletion region DR may be formed at and around the interface between the third well 126 and the first well 104.

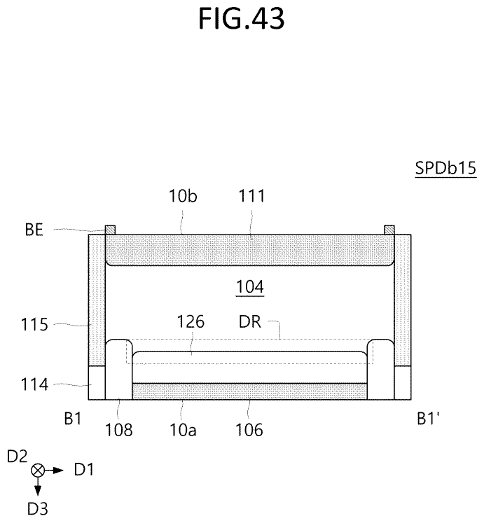

Referring to FIG. 43, a single photon detection device SPDb15 may be provided. Unlike some example embodiments, including the example embodiments illustrated in FIG. 42, the heavily doped region 106 and the third well 126 may have substantially the same width. The side surface of the heavily doped region 106 may be aligned with the side surface of the third well 126. For example, the side surface of the heavily doped region 106 may be coplanar with the side surface of the third well 126.

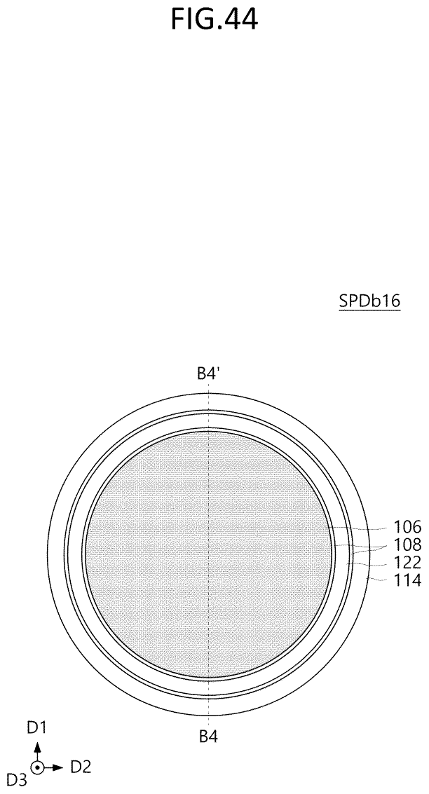

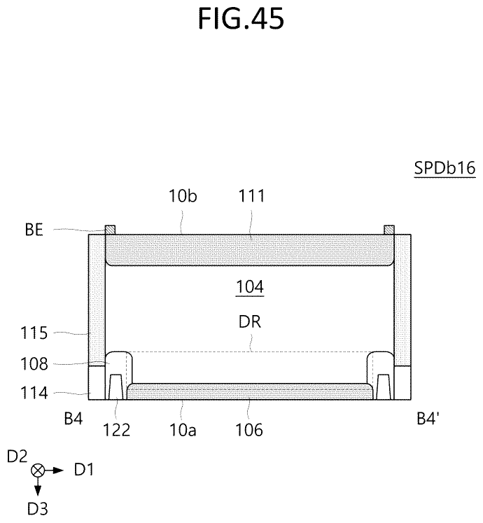

FIG. 44 is a plan view illustrating a frontside of a single photon detection device according to some example embodiments. FIG. 45 is a cross-sectional view corresponding to line B4-B4′ of FIG. 44 according to some example embodiments. For the brevity of explanation, differences from that described with reference to FIGS. 24 to 26 are described.

Referring to FIGS. 44 and 45, a single photon detection device SPDb16 may be provided. Unlike some example embodiments, including the example embodiments illustrated in FIGS. 24 to 26, the single photon detection device SPDb16 may include a second insulation pattern 122. The second insulation pattern 122 may be provided on the guard ring 108. The second insulation pattern 122 may overlap with the guard ring 108 along the third direction D3. The second insulation pattern 122 may surround the heavily doped region 106. For example, the second insulation pattern 122 may have a ring shape extending along the side surface of the heavily doped region 106. In some example embodiments, the second insulation pattern 122 may be spaced apart from the heavily doped region 106. In some other example embodiments, the second insulation pattern 122 may directly contact the heavily doped region 106. The second insulation pattern 122 may be formed from the same level as the bottom surface of the heavily doped region 106 to a certain depth. The depth of the second insulation pattern 122 may be determined as needed. The second insulation pattern 122 may be inserted into the guard ring 108. For example, the side surfaces and top surface of the second insulation pattern 122 may directly contact the guard ring 108. The bottom surface of the second insulation pattern 122 may be exposed to the bottom surface of the semiconductor substrate.

The second insulation pattern 122 may include an electrically insulating material. For example, the second insulation pattern 122 may include silicon oxide (e.g., SiO₂), silicon nitride (e.g., SiN), silicon oxynitride (e.g., SiON), or combinations thereof. In some example embodiments, the second insulation pattern 122 may be STI formed by etching a portion of the semiconductor substrate and then filling the etched region with an electrically insulating material. The second insulation pattern 122 may alleviate a concentration of the electric field on a portion of the depletion region DR, thereby reducing or preventing the premature breakdown phenomenon. The second insulation pattern 122 may reduce or prevent the influence of surface noise components. The second insulation pattern 122 may be formed in the semiconductor substrate before the first well 104 and the guard ring 108. The second insulation pattern 122 may reduce the doping concentration of the region positioned between the second insulation pattern 122 and the backside surface 10b. For example, in the ion implantation process of implanting impurities into the semiconductor substrate to form the first well 104 and the guard ring 108, the second insulation pattern 122 may be configured to lower the ion implantation effect on the region where the first well 104 and the guard ring 108 are formed. Compared to the case without the second insulation pattern 122, the doping concentration of the first well 104 and the guard ring 108 positioned below the second insulation pattern 122 may be decreased with the second insulation pattern 122. Accordingly, the depletion region DR may be formed widely, which may allow the guard ring 108 to function more effectively, and the fill factor and photoelectric conversion efficiency of the single photon detection device SPDb16 may be improved.

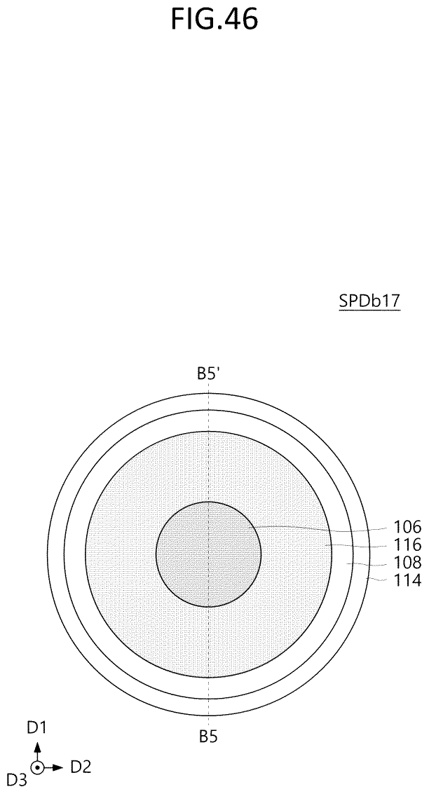

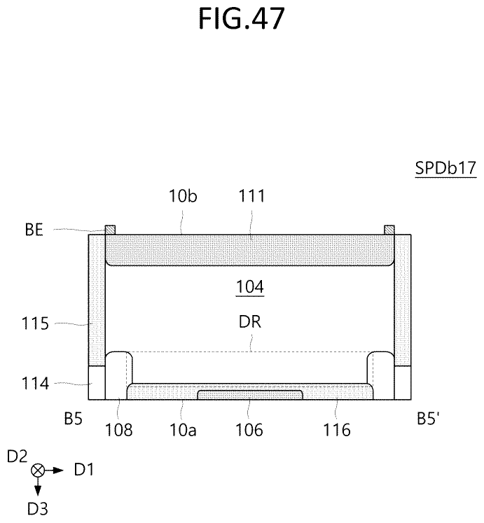

FIG. 46 is a plan view illustrating a frontside of a single photon detection device according to some example embodiments. FIG. 47 is a cross-sectional view corresponding to line B5-B5′ of FIG. 46 according to some example embodiments. For the brevity of explanation, differences from that described with reference to FIGS. 24 to 26 are described.

Referring to FIGS. 46 and 47, a single photon detection device SPDb17 may be provided. Unlike some example embodiments, including the example embodiments illustrated in FIGS. 24 to 26, the single photon detection device SPDb17 may include a second lightly doped region 116. The second lightly doped region 116 may be provided between the heavily doped region 106 and the first well 104. The second lightly doped region 116 may contact the top surface and side surface of the heavily doped region 106. The second lightly doped region 116 may be exposed on the frontside surface 10a. The second lightly doped region 116 may surround the heavily doped region 106 on the frontside surface 10a. The second lightly doped region 116 may have the second conductivity type. The second lightly doped region 116 may have a lower doping concentration than that of the heavily doped region 106. For example, the doping concentration of the second lightly doped region 116 may be 1×10¹⁵˜1×10¹⁹ cm⁻³. The second lightly doped region 116 may form a depletion region DR by contacting the first well 104. The second lightly doped region 116 may be configured to reduce or prevent the tunneling effect that occurs as the size of the semiconductor device becomes smaller. For example, the tunneling effect may be current flowing even when no photon has entered the single photon detection device SPDa15. By using the second lightly doped region 116 to form the depletion region DR, the tunneling noise and trap-assisted tunneling noise of the single photon detection device SPDa15 may be reduced, and the operating wavelength range of the single photon detection device SPDb16 may be broadened.

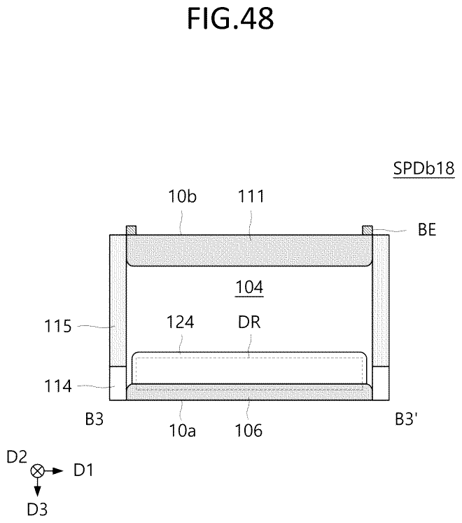

FIG. 48 is a cross-sectional view corresponding to line B3-B3′ of FIGS. 29 and 30 according to some example embodiments. For the brevity of explanation, differences from that described with reference to FIGS. 29 to 31 are described.

Referring to FIG. 48, a single photon detection device SPDb18 may be provided. Unlike some example embodiments, including the example embodiments illustrated in FIGS. 29 and 30, the single photon detection device SPDb18 may include a second well 124. The second well 124 may be provided between the first well 104 and the heavily doped region 106. The second well 124 may directly contact the first well 104 and the heavily doped region 106. The second well 124 may have the first conductivity type. For example, a doping concentration of the second well 124 may be 1×10¹⁵˜5×10¹⁷ cm⁻³. In some example embodiments, the second well 124 may have the uniform doping concentration. In some example embodiments, the doping concentration of the second well 124 may decrease as it approaches the heavily doped region 106. However, the distribution of the doping concentration of the second well 124 may be determined as needed. For example, the doping concentration of the second well 124 may increase as it approaches to the heavily doped region 106, or may increase and then decrease as it approaches to the heavily doped region 106. The second well 124 may enhance the avalanche effect by increasing the electric field of the depletion region DR. The second well 124 may be configured to improve the characteristics of carriers (i.e., electrons or holes) transferring from the first well 104 to the heavily doped region 106.

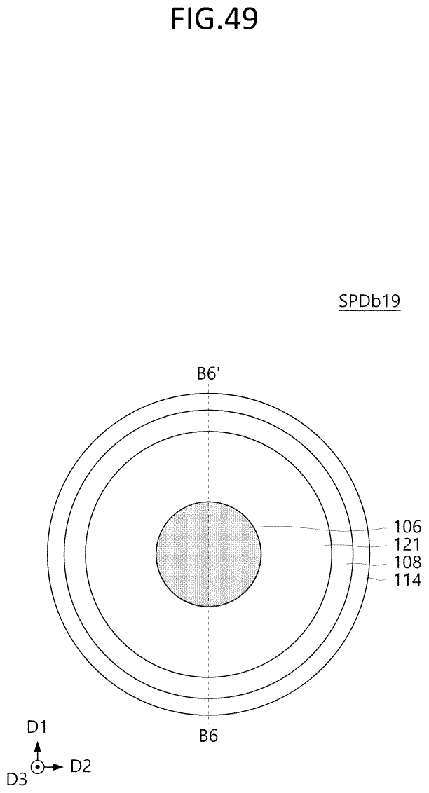

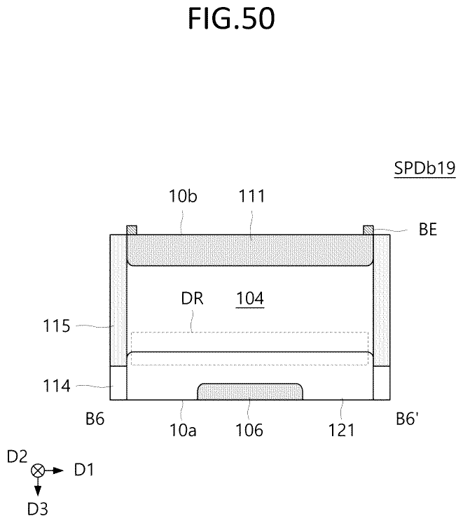

FIG. 49 is a plan view illustrating a frontside of a single photon detection device according to some example embodiments. FIG. 50 is a cross-sectional view corresponding to line B6-B6′ of FIG. 49 according to some example embodiments. For the brevity of explanation, differences from that described with reference to FIGS. 24 to 26 are described.

Referring to FIGS. 49 and 50, a single photon detection device SPDb19 may be provided. Unlike some example embodiments, including the example embodiments illustrated in FIGS. 24 to 26, the single photon detection device SPDb19 may include a first lightly doped region 121. The first lightly doped region 121 may be provided between the first well 104 and the heavily doped region 106. The first lightly doped region 121 may space apart the heavily doped region 106 and the first well 104. The first lightly doped region 121 may have the second conductivity type. A doping concentration of the first lightly doped region 121 may be lower than the doping concentration of the heavily doped region 106. For example, the doping concentration of the first lightly doped region 121 may be 1×10¹⁶˜1×10¹⁸ cm⁻³.

As the first lightly doped region 121 and the first well 104 have different conductivity types, a depletion region DR may be formed at and around the interface between the first lightly doped region 121 and the first well 104. The depletion region DR may be configured to multiply charges generated in the depletion region DR and charges transferred to the depletion region DR. For example, when the single photon detection device SPDb19 is operated, an electric field of 3×10⁵ V/cm or more may be applied to the depletion region DR. The depletion region DR may be referred to as a multiplication region.

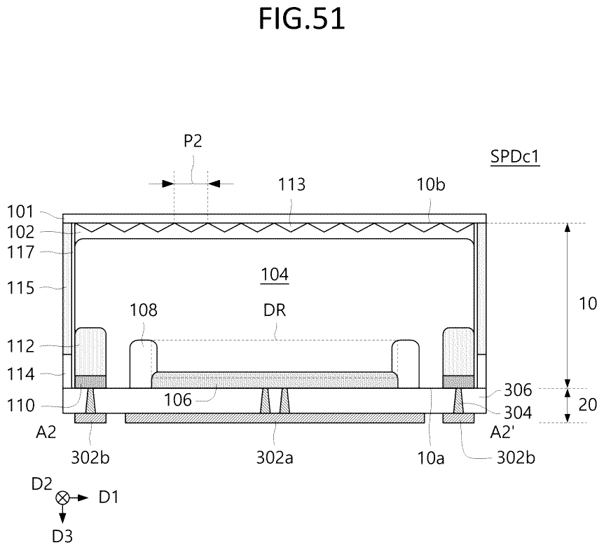

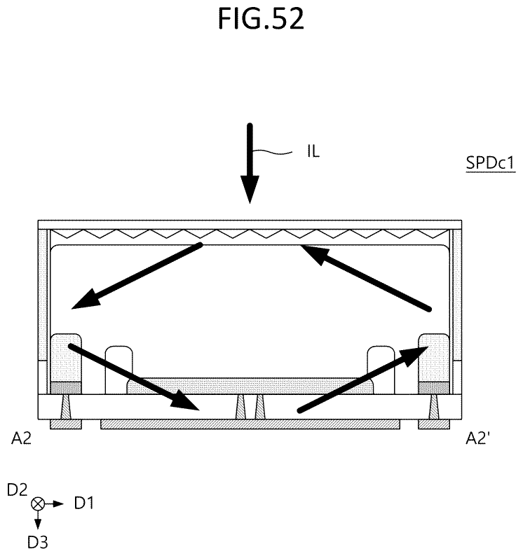

FIG. 51 is a cross-sectional view corresponding to line A2-A2′ of FIG. 4 according to some example embodiments. FIG. 52 is a cross-sectional view corresponding to line A2-A2′ of FIG. 4 according to some example embodiments, explaining the path of incident light for the single photon detection device of FIG. 51. For the brevity of explanation, differences from that described with reference to FIGS. 4 and 5 are described.

Referring to FIG. 51, a single photon detection device SPDc1 may be provided. Unlike some example embodiments, including the example embodiments illustrated in FIGS. 4 and 5, the single photon detection device SPDc1 may include a backside reflection layer 101 and a side reflection layer 117. The backside reflection layer 101 may transmit incident light. In other words, incident light may penetrate the backside reflection layer 101 and be provided to the photodetection layer 10. The backside reflection layer 101 may reflect light incident from the photodetection layer 10 to the backside reflection layer 101. For example, the backside reflection layer 101 may include a stacked structure of dielectric films (e.g., silicon oxide (e.g., SiO₂), silicon nitride (e.g., SiN), silicon oxynitride (e.g., SiON), aluminum oxide (e.g., Al₂O₃), hafnium oxide (e.g., HfO₂), zirconium oxide (zirconia, ZrO₂), tantalum oxide (TaO), or combinations thereof), a transparent electrode (e.g., indium tin oxide (ITO), indium zinc oxide (IZO), zinc oxide (ZnO), indium oxide (In₂O₃), indium gallium oxide (IGO), aluminum-doped zinc oxide (AZO), graphene, silver nanowires, conductive polymers (e.g., PEDOT.PSS), radical polymers, or combinations thereof), a stacked structure of amorphous silicon (a-Si) and at least one metal thin-film (e.g., gold (Au) thin-film), or a stacked structure of high refractive index materials (e.g., hafnium oxide (HfO₂), zirconium oxide (zirconia, ZrO₂), tantalum oxide (TaO), metal pattern, metal particle array, metamaterial, or combinations thereof) and at least one metal thin-film (e.g., gold (Au) thin-film).

The side reflection layer 117 may be provided on an inner sidewall (i.e., an sidewall facing the first well 104) of the device isolation pattern 114 and the vertical isolation pattern 115. The side reflection layer 117 may reflect light incident on the side reflection layer 117. In some example embodiments, the side reflection layer 117 may be formed by doping the inner sidewall of the device isolation pattern 114 and the vertical isolation pattern 115 with a material having high reflectivity. For example, the material having high reflectivity may be boron. In some example embodiments, the side reflection layer 117 may be provided on the inner sidewall of the device isolation pattern 114 and the vertical isolation pattern 115. In some other example embodiments, the side reflection layer 117 may be omitted, and the device isolation pattern 114 and the vertical isolation pattern 115 may reflect light incident from the side.

Unlike some example embodiments, including the example embodiments illustrated in FIGS. 4 and 5, the backside patterns 113 may have second pitches P2. The second pitch P2 may be larger than the first pitch P1 described above. The second pitch P2 may be similar to or slightly smaller than the wavelength of the light to be detected. For example, when the wavelength of the light to be detected is approximately 940 nanometers (nm), the second pitch P2 may be approximately 600 nanometers (nm) to approximately 900 nanometers (nm). Accordingly, the light to be detected may be diffracted by the backside patterns 113. As illustrated in FIG. 52, the incident light IL may be diffracted by the backside patterns 113 and then reflected by the side reflection layer 117, the backside reflection layer 101, the output pattern 302a, and the bias pattern 302b. The optical path of the incident light IL within the semiconductor substrate may be extended. The light absorption efficiency of the semiconductor substrate for light with energy higher than the bandgap energy of the semiconductor substrate may increase as the optical path length within the semiconductor substrate becomes longer. The light absorption efficiency may improve as the optical path length of the incident light IL increases. In some example embodiments, as the optical path of the incident light IL increases, the required thickness of the photodetection layer 10 for detecting light with a long absorption distance (e.g., near-infrared light) may be decreased. In some example embodiments, resonance of incident light may occur within the photodetection layer 10. In other words, the side reflection layer 117, the backside reflection layer 101, the output pattern 302a, and the bias pattern 302b may form a resonant structure for incident light.

The present disclosure may provide the single photon detection device SPDc1 that may increase light absorption efficiency by extending the path of incident light within the photodetection layer 10, while minimizing the increase in the thickness of the photodetection layer 10 required for detecting light with a long absorption distance.

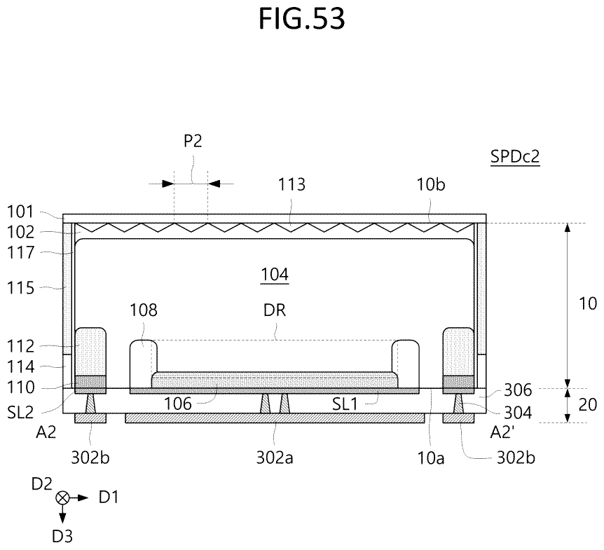

FIG. 53 is a cross-sectional view corresponding to line A2-A2′ of FIG. 4 according to some example embodiments. For the brevity of explanation, differences from that described with reference to FIG. 51 are described.

Referring to FIG. 53, a single photon detection device SPDc2 may be provided. Unlike some example embodiments, including the example embodiments illustrated in FIG. 51, the single photon detection device SPDc2 may further include a first silicide layer SL1 and a second silicide layer SL2.

The first silicide layer SL1 may be provided between the heavily doped region 106 and the vertical connection portion 304. The first silicide layer SL1 may extend on the guard ring 108. In some example embodiments, the first silicide layer SL1 may be formed horizontally up to substantially the same position as the outer side surface of the guard ring 108, completely covering the bottom surface of the guard ring 108. For example, a side surface of the first silicide layer SL1 may be coplanar with the outer side surface of the guard ring 108. In some other example embodiments, the first silicide layer SL1 may be formed horizontally up to the inside of the outer side surface of the guard ring 108, partially covering the bottom surface of the guard ring 108. For example, the side surface of the first silicide layer SL1 may be shifted inward from the outer side surface of the guard ring 108. The first silicide layer SL1 may be electrically connected to the heavily doped region 106, the guard ring 108, and the vertical connection portion 304. For example, the first silicide layer SL1 may directly contact the heavily doped region 106, the guard ring 108, and the vertical connection portion 304. The first silicide layer SL1 may improve the electrical connection characteristics between the heavily doped region 106, the guard ring 108, and the vertical connection portion 304. For example, the first silicide layer SL1 may reduce the contact resistance between the heavily doped region 106 and the vertical connection portion 304. The first silicide layer SL1 may reduce or prevent a voltage drop when a voltage is applied to the heavily doped region 106 and the guard ring 108 through the first silicide layer SL1. The first silicide layer SL1 may be configured to allow the voltage to be uniformly applied to the heavily doped region 106 and the guard ring 108. The first silicide layer SL1 and the heavily doped region 106 may form a Schottky junction. For example, the first silicide layer SL1 may include at least one of chromium silicide (CrSi), manganese silicide (MnSi), iron silicide (FeSi), cobalt silicide (CoSi), nickel silicide (NiSi), sodium silicide (NaSi), magnesium silicide (Mg₂Si), platinum silicide (PtSi), titanium silicide (TiSi₂), tungsten silicide (WSi₂), molybdenum silicide (MoSi₂), strontium silicide (SrSi₂), thorium silicide (ThSi₂), uranium silicide (USi), hafnium silicide (HfSi₂), and neodymium silicide (NdSi₂).

The second silicide layer SL2 may be provided between the contact region 110 and the vertical connection portion 304. In some example embodiments, the second silicide layer SL2 may be formed exclusively on the contact region 110. In some other example embodiments, the second silicide layer SL2 may extend on the first well 104, covering a portion of the bottom surface of the first well 104 exposed between the contact region 110 and the guard ring 108. The second silicide layer SL2 may be electrically connected to the contact region 110 and the vertical connection portion 304. For example, the second silicide layer SL2 may directly contact the contact region 110 and the vertical connection portion 304. The second silicide layer SL2 may improve the electrical connection characteristics between the contact region 110 and the vertical connection portion 304. For example, the second silicide layer SL2 may reduce the contact resistance between the contact region 110 and the vertical connection portion 304. The second silicide layer SL2 may reduce or prevent a voltage drop when a voltage is applied to the contact region 110 through the second silicide layer SL2. The second silicide layer SL2 may be configured to allow voltage to be uniformly applied to the contact region 110. The second silicide layer SL2 may include at least one of chromium silicide (CrSi), manganese silicide (MnSi), iron silicide (FeSi), cobalt silicide (CoSi), nickel silicide (NiSi), sodium silicide (NaSi), magnesium silicide (Mg₂Si), platinum silicide (PtSi), titanium silicide (TiSi₂), tungsten silicide (WSi₂), molybdenum silicide (MoSi₂), strontium silicide (SrSi₂), thorium silicide (ThSi₂), uranium silicide (USi), hafnium silicide (HfSi₂), and neodymium silicide (NdSi₂).

The first well 104 may be exposed between the first silicide layer SL1 and the second silicide layer SL2. When the first silicide layer SL1 extends on the first well 104, an electrical short may occur between the first silicide layer SL1 and the second silicide layer SL2. The present disclosure may provide that the first silicide layer SL1 and the second silicide layer SL2 may be sufficiently spaced apart to prevent the electrical short therebetween.

The light absorption efficiency of the semiconductor substrate for light with energy higher than the bandgap energy of the semiconductor substrate may increase as the optical path within the semiconductor substrate becomes longer. The first silicide layer SL1 and the second silicide layer SL2 may reflect light back into the photodetection layer 10. Accordingly, the light absorption efficiency of the semiconductor substrate for light with energy higher than the bandgap energy of the semiconductor substrate may be improved.

Light with energy smaller than the bandgap energy of the semiconductor substrate (e.g., light with wavelengths of 1100 nm to 1600 nm for a silicon substrate) may not be sufficiently absorbed in the photodetection layer 10 and may penetrate the photodetection layer 10. As the first silicide layer SL1 and the heavily doped region 106 form a Schottky junction, a Schottky barrier may be formed between the first silicide layer SL1 and the heavily doped region 106. When the single photon detection device SPDc1 is operated, the height of the Schottky barrier between the first silicide layer SL1 and the semiconductor substrate may be determined to be smaller than the bandgap energy of the semiconductor substrate. For example, the material constituting the first silicide layer SL1 may be selected so that the height of the Schottky barrier between the first silicide layer SL1 and the semiconductor substrate is smaller than the bandgap energy of the semiconductor substrate. Long-wavelength light (e.g., light with wavelengths of 1100 nm to 1600 nm) that penetrates the semiconductor substrate may excite carriers within the semiconductor substrate. The carriers excited from the first silicide layer SL1 into the semiconductor substrate may be referred to as hot carriers. The hot carriers may be transferred to the multiplication region by the electric field and be multiplied in the multiplication region. Accordingly, the single photon detection device SPDc2 may detect long-wavelength light that the semiconductor substrate does not sufficiently absorb.

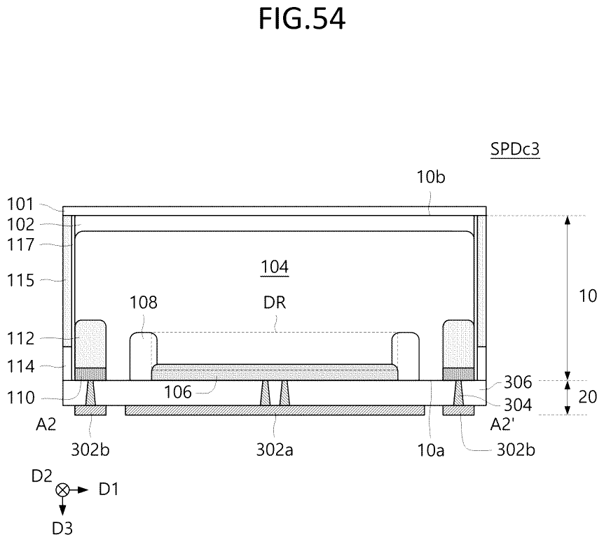

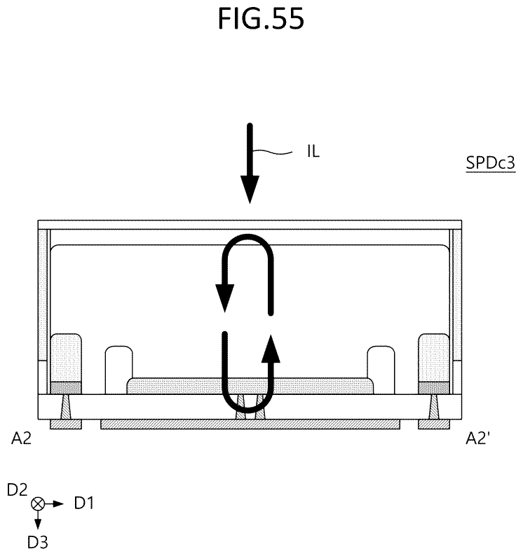

FIG. 54 is a cross-sectional view corresponding to line A2-A2′ of FIG. 4 according to some example embodiments. FIG. 55 is a cross-sectional view corresponding to line A2-A2′ of FIG. 4 according to some example embodiments, explaining the path of incident light for the single photon detection device of FIG. 54. For the brevity of explanation, differences from that described with reference to FIG. 51 are described.

Referring to FIG. 54, a single photon detection device SPDc3 may be provided. Unlike some example embodiments, including the example embodiments illustrated in FIG. 51, the single photon detection device SPDc3 may not include the backside patterns 113. As illustrated in FIG. 55, the incident light IL may be reflected vertically between the output pattern 302a and the backside reflection layer 101. Accordingly, the path of incident light within the photodetection layer 10 may be increased, and the light absorption efficiency of the photodetection layer 10 may be improved.

Unlike some example embodiments, including the example embodiments illustrated in FIG. 51, the backside reflection layer 101 may include a stacked structure of dielectric films (e.g., silicon oxide (e.g., SiO₂), silicon nitride (e.g., SiN), silicon oxynitride (e.g., SiON), aluminum oxide (e.g., Al₂O₃), hafnium oxide (e.g., HfO₂), zirconium oxide (zirconia, ZrO₂), tantalum oxide (TaO), or combinations thereof), a stacked structure of amorphous silicon (a-Si) and at least one metal thin-film (e.g., gold (Au) thin-film), or a stacked structure of high refractive index materials (e.g., hafnium oxide (HfO₂), zirconium oxide (zirconia, ZrO₂), tantalum oxide (TaO), metal pattern, metal particle array, metamaterial, or combinations thereof) and at least one metal thin-film (e.g., gold (Au) thin-film).

In some example embodiments, the single photon detection device SPDc3 may not include the side reflection layer 117. In some example embodiments, the single photon detection device SPDc3 may include the first silicide layer SL1 and the second silicide layer SL2 described with reference to FIG. 53.

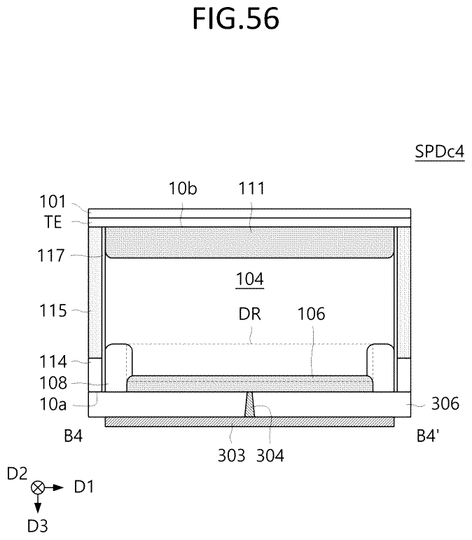

FIG. 56 is a cross-sectional view corresponding to line B1-B1′ of FIGS. 24 and 25 according to some example embodiments. For the brevity of explanation, differences from that described with reference to FIG. 33 and FIG. 51 are described.

Referring to FIG. 56, a single photon detection device SPDc4 may be provided. Unlike some example embodiments, including the example embodiments illustrated in FIG. 33, the single photon detection device SPDc4 may include a backside reflection layer 101 and a side reflection layer 117. The backside reflection layer 101 may be substantially the same as the backside reflection layer 101 described with reference to FIG. 51, except for its position. In some example embodiments, the backside reflection layer 101 may be provided on the transparent electrode TE. In some other example embodiments, the single photon detection device SPDc4 may include a back electrode BE instead of the transparent electrode TE, and the backside reflection layer 101 may cover the vertical contact region 111 exposed between the back electrodes BE.

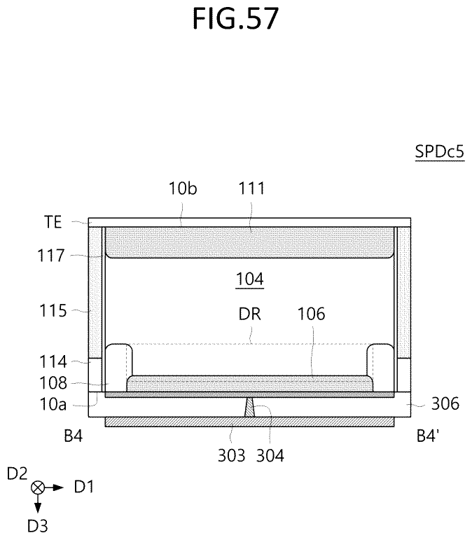

FIG. 57 is a cross-sectional view corresponding to line B1-B1′ of FIGS. 24 and 25 according to some example embodiments. For the brevity of explanation, differences from that described with reference to FIG. 53 and FIG. 56 are described.

Referring to FIG. 57, a single photon detection device SPDc5 may be provided. Unlike some example embodiments, including the example embodiments illustrated in FIG. 56, the single photon detection device SPDc5 may further include a first silicide layer SL1. The first silicide layer SL1 may be substantially the same as the first silicide layer SL1 described with reference to FIG. 53.

Accordingly, the single photon detection device SPDc5 with improved light absorption efficiency that may detect long-wavelength light not sufficiently absorbed by the semiconductor substrate may be provided.

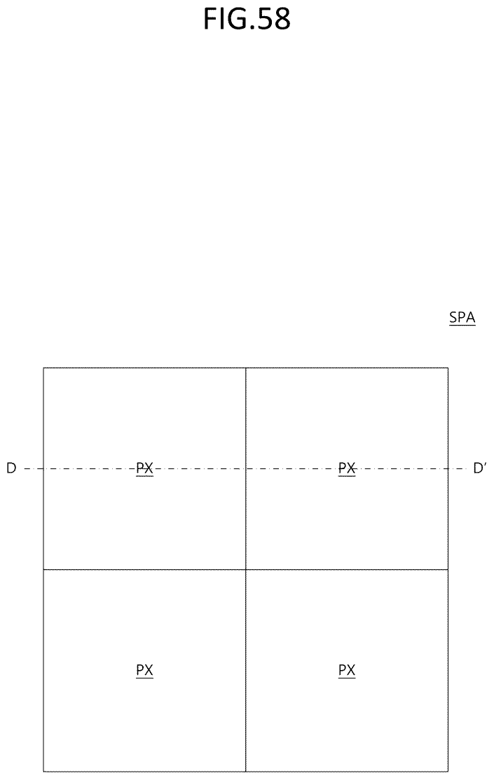

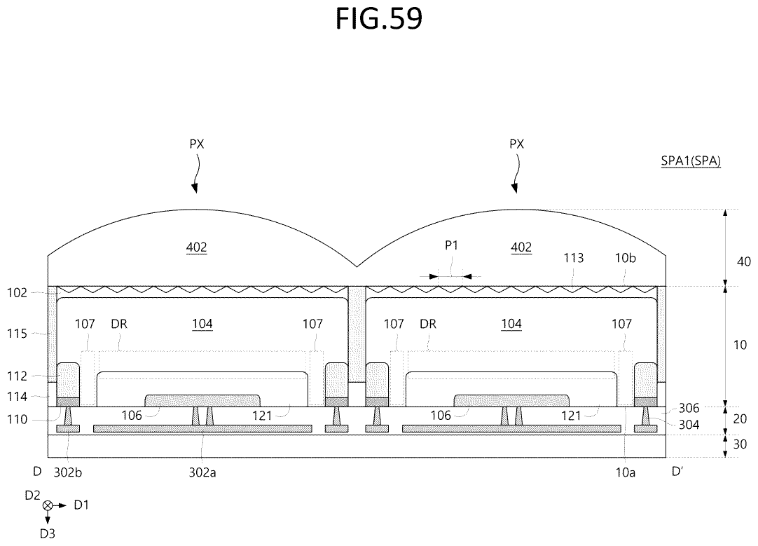

FIG. 58 is a plan view of a single photon detection device array according to some example embodiments. FIG. 59 is a cross-sectional view corresponding to line D-D′ of FIG. 58 according to some example embodiments. For the brevity of explanation, features that are the same or substantially the same as that described with reference to FIGS. 1 and 2 may not be described.

Referring to FIGS. 58 and 59, a single photon detection device array SPA1(SPA) may be provided. The single photon detection device array SPA1(SPA) may include pixels PX arranged in two dimensions. Each of the pixels PX may include the single photon detection device SPDa1 described with reference to FIGS. 1 and 2. The photodetection layers 10 of the single photon detection devices SPDa1 may be connected to form the photodetection layer 10 of the single photon detection device array SPA1(SPA). The connection layers 20 of the single photon detection devices SPDa1 may be connected to form the connection layer 20 of the single photon detection device array SPA1(SPA).

The single photon detection device array SPA1 may include a control layer 30 provided on the opposite side of the photodetection layer 10 with respect to the connection layer 20. The control layer 30 may include circuits necessary for the operation of the photodetection layer 10. For example, the control layer 30 may be in the form of a separate chip where the circuit is formed. The circuits may be implemented by various electronic devices as needed. The circuits may include a quenching resistor (or quenching circuit) and pixel circuits. The quenching resistor (or quenching circuit) may be configured to stop the avalanche effect and allow the photodetection layer 10 to detect another photon. The pixel circuits may consist of reset or recharge circuits, memory, amplification circuits, counters, gate circuits, time-to-digital converters, and the like. The circuits may also include DC-DC converters and other power management integrated circuits. The circuits may transmit signals to the photodetection layer 10 or receive signals from the photodetection layer 10. Specifically, the circuits of the control layer 30 may be electrically connected to the output pattern 302a and the bias pattern 302b, and electrical signals may be transmitted/received through an electrode (e.g., through-silicon via) penetrating from the backside surface 10b to the frontside surface 10a of the substrate.

The single photon detection device array SPA1 may include an optical element layer 40 provided on the opposite side of the photodetection layer 10 with respect to the connection layer 20. The optical element layer 40 may be provided on the backside surface 10b of the substrate 100. The optical element layer 40 may be a component for effectively detecting incident light in the photodetection layer 10 by refracting, diffracting, or scattering the path of incident light. The optical element layer 40 may include a lens 402. The lens 402 may focus incident light and transmit it to the photodetection layer 10. For example, the lens 402 may include a microlens, a Fresnel lens, or a metalens. However, the type of lens 402 is not limited and may be determined as needed. In some example embodiments, in each pixel PX, the central axis of the lens 402 may be aligned with the central axis of the photodetection layer 10. The central axis of the lens 402 and the central axis of the photodetection layer 10 may be virtual axis parallel to the stacking direction of the photodetection layer 10 and the lens 402 (i.e., the opposite direction of the third direction D3) passing through the centers of the lens 402 and the photodetection layer 10, respectively. In some example embodiments, the central axis of the lens 402 may be misaligned with the central axis of the photodetection layer 10. In some example embodiments, a width of the lens 402 may be approximately half a width of the photodetection layer 10. In some example embodiments, the lenses 402 may be arranged in a 2×2 array. In some example embodiments, the optical element layer 40 may further include at least one optical element between the lens 402 and the photodetection layer 10. For example, the optical element may be a color filter, a bandpass filter, a metal grid, an air grid, a low refractive index material-based grid, an anti-reflection coating, a 2D nanomaterial layer, or an organic material layer. In some example embodiments, the anti-reflective coating may be formed on the lens 402.

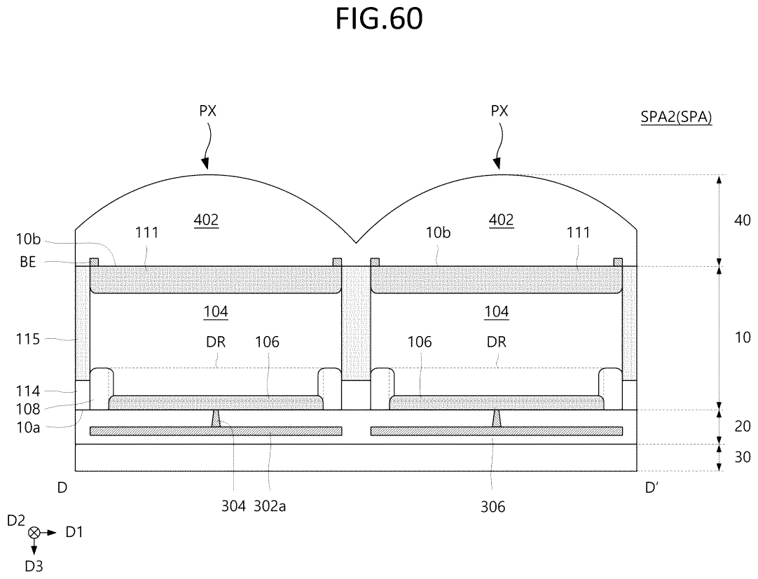

FIGS. 60, 61, and 62 are cross-sectional views corresponding to line D-D′ of FIG. 58 according to some example embodiments. For the brevity of explanation, features that are the same or substantially the same as that described with reference to FIGS. 24 to 26 and FIGS. 58 and 59 may not be explained.

Referring to FIGS. 58 and 60, a single photon detection device array SPA2(SPA) may be provided. The single photon detection device array SPA2(SPA) may include pixels PX arranged in two dimensions. Each of the pixels PX may include the single photon detection device SPDb1 described with reference to FIGS. 24 to 26. The single photon detection devices SPDb1 may be connected to form the photodetection layer 10 of the single photon detection device array SPA2(SPA).

The single photon detection device array SPA2(SPA) may include a connection layer 20 and a control layer 30 sequentially arranged on the frontside surface 10a of the single photon detection devices SPDb1, and an optical element layer 40 provided on the backside surface 10b of the single photon detection devices SPDb1. The connection layer 20, control layer 30, and optical element layer 40 may be substantially the same as the connection layer 20, the control layer 30, and the optical element layer 40 illustrated in FIGS. 58 and 59. However, as the single photon detection device array SPA2(SPA) includes a vertical contact region 111 instead of the contact region 110, the bias pattern 302b may not be provided.

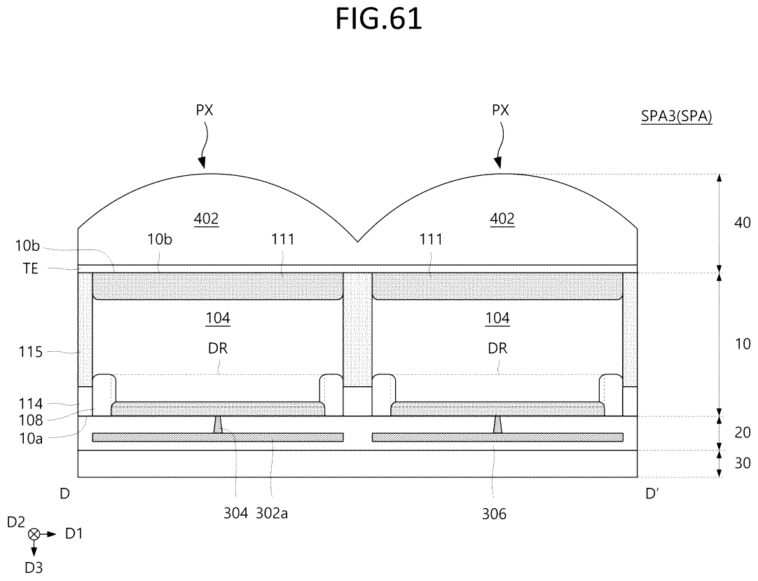

Referring to FIGS. 58 and 61, a single photon detection device array SPA3(SPA) may be provided. The single photon detection device array SPA3(SPA) may include pixels PX arranged in two dimensions. Each of the pixels PX may include the single photon detection device SPDb5 described with reference to FIG. 33. The single photon detection devices SPDb5 may be connected to form the photodetection layer 10 of the single photon detection device array SPA3(SPA).

The single photon detection device array SPA3(SPA) may include a connection layer 20 and a control layer 30 sequentially arranged on the frontside surface 10a of the single photon detection devices SPDb5, and an optical element layer 40 provided on the backside surface 10b of the single photon detection devices SPDb5. The connection layer 20, the control layer 30, and the optical element layer 40 may be substantially the same as the connection layer 20, the control layer 30, and the optical element layer 40 illustrated in FIG. 60.

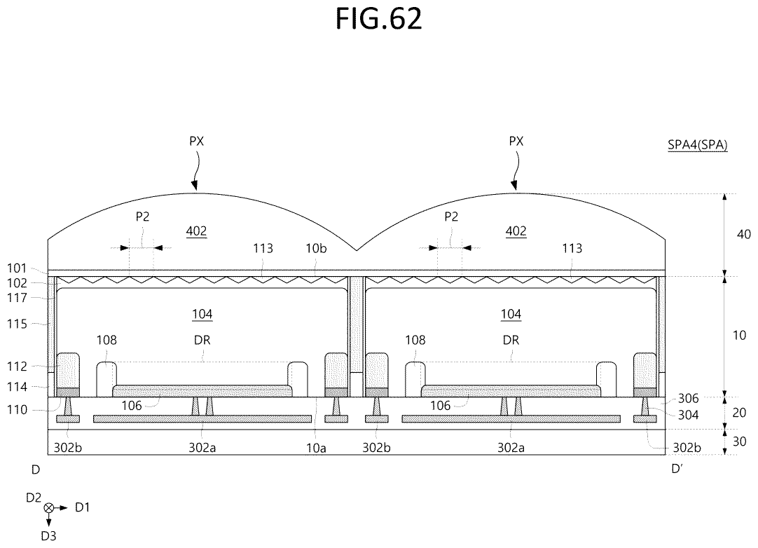

Referring to FIGS. 58 and 62, a single photon detection device array SPA4(SPA) may be provided. The single photon detection device array SPA4(SPA) may include pixels PX arranged in two dimensions. Each of the pixels PX may include the single photon detection device SPDc1 described with reference to FIG. 51. The photodetection layers 10 of the single photon detection devices SPDc1 may be connected to form the photodetection layer 10 of the single photon detection device array SPA4(SPA). The connection layers 20 of the single photon detection devices SPDc1 may be connected to form the connection layer 20 of the single photon detection device array SPA4(SPA).

The single photon detection device array SPA4(SPA) may include a control layer 30 provided on the opposite side of the photodetection layer 10 with respect to the connection layer 20. The single photon detection device array SPA4(SPA) may include an optical element layer 40 provided on the opposite side of the connection layer 20 with respect to the photodetection layer 10. The control layer 30 and the optical element layer 40 may be substantially the same as the control layer 30 and the optical element layer 40 illustrated in FIG. 59.

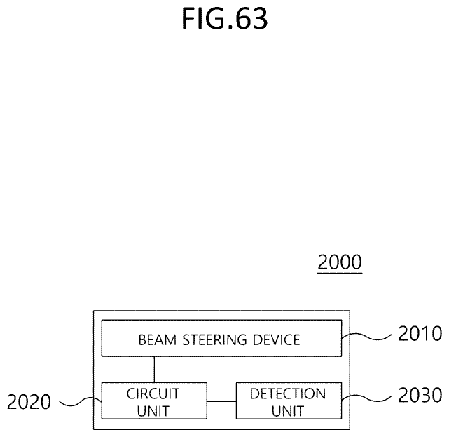

FIG. 63 is a block diagram for explaining an electronic device according to some example embodiments.

Referring to FIG. 63, an electronic device 2000 may be provided. The electronic device 2000 may radiate light towards a subject (not illustrated) and detect light reflected by the subject and returned to the electronic device 2000. The electronic device 2000 may include a beam steering device 2010. The beam steering device 2010 may adjust the irradiation direction of light emitted from the electronic device 2000. The beam steering device 2010 may be a mechanical or non-mechanical (semiconductor) beam steering device. The electronic device 2000 may include a light source unit within the beam steering device 2010 or may include a light source unit separately provided from the beam steering device 2010. The beam steering device 2010 may be a scanning-type light emitting device. However, the light emitting device of the electronic device 2000 may not be limited to the beam steering device 2010. In some other example embodiments, the electronic device 2000 may include a flash-type light emitting device instead of the beam steering device 2010 or together with the beam steering device 2010. The flash-type light emitting device may radiate light to a region including the entire field of view at once without a scanning process.

The light steered by the beam steering device 2010 may be reflected by the subject and return to the electronic device 2000. The electronic device 2000 may include a detection unit 2030 for detecting the light reflected by the subject. The detection unit 2030 may include a plurality of photodetection devices and may further include other optical elements. The plurality of photodetection devices may include any one of the single photon detection devices SPDa1 to SPDc5 described above. In some other example embodiments, the electronic device 2000 may further include a circuit unit 2020 connected to at least one of the beam steering device 2010 and the detection unit 2030. The circuit unit 2020 may include a computation unit for acquiring and processing data, and may further include a driving unit and a control unit, and the like. In some other example embodiments, the circuit unit 2020 may further include a power unit and memory, and the like.

Although the electronic device 2000 is illustrated as including the beam steering device 2010 and the detection unit 2030 in a single device, the beam steering device 2010 and the detection unit 2030 may not be provided in the single device. The beam steering device 2010 and the detection unit 2030 may be provided separately in separate devices. In some example embodiments, the circuit unit 2020 may be connected to the beam steering device 2010 or the detection unit 2030 through wireless communication without wiring.

The electronic device 2000 according to some example embodiments described above may be applied to various electronic devices. For example, the electronic device 2000 may be applied to a light detection and ranging (LiDAR) device. The LiDAR device may be a phase-shift type or time-of-flight (TOF) type device. In addition, the single photon detection devices SPD1 to SPD23 according to some example embodiments or the electronic device 2000 including the same may be embedded in electronic devices such as smartphones, wearable devices (e.g., glasses-type devices implementing augmented reality and virtual reality), Internet of Things (IoT) devices, home appliances, a tablet personal computers (PCs), personal digital assistants (PDAs), portable multimedia players (PMPs), navigation systems, drones, robots, unmanned vehicles, autonomous vehicles, advanced drivers assistance systems (ADAS), and the like.

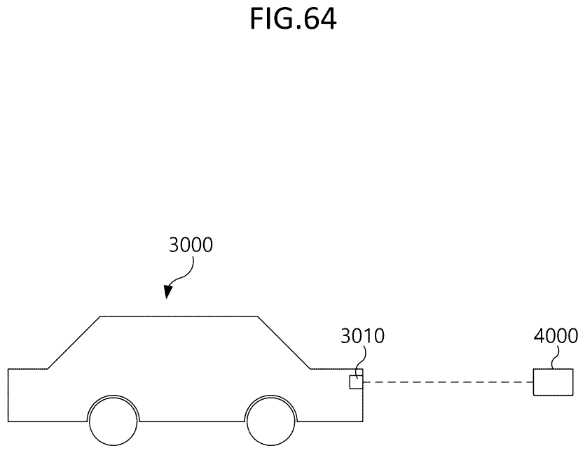

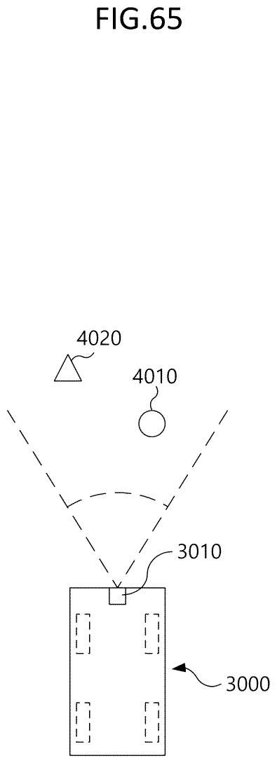

FIGS. 64 and 65 are conceptual diagrams illustrating cases in which a LiDAR device is applied to a vehicle according to some example embodiments.

Referring to FIGS. 64 and 65, a LiDAR device 3010 may be applied to a vehicle 3000. Information on a subject 4000 may be acquired using the LiDAR device 3010 applied to the vehicle 3000. The vehicle 3000 may be an automobile having an autonomous driving function. The LiDAR device 3010 may detect objects or people (i.e., subjects 4000) in a direction in which the vehicle 3000 moves. The LiDAR device 3010 may measure the distance to the subject 4000 using information such as a time difference between a transmitted signal and a detection signal. The LiDAR device 3010 may acquire information about nearby subjects 4010 and distant subjects 4020 within the scanning range. The LiDAR device 3010 may include the electronic device 2000 described with reference to FIG. 63. Although the LiDAR device 3010 is disposed in front of the vehicle 3000 to detect subjects 4000 in the direction in which the vehicle 3000 moves, this is not limited. In some other example embodiments, the LiDAR device 3010 may be disposed at a plurality of locations on the vehicle 3000 to detect all subjects 4000 around the vehicle 3000. For example, four LiDAR devices 3010 may be disposed on the frontside, backside, and both sides of the vehicle 3000, respectively. In some other example embodiments, the LiDAR device 3010 may be disposed on the roof of the vehicle 3000, rotate, and detect all subjects 4000 around the vehicle 3000.

The above description of some embodiments of the inventive concepts provides examples for explanation of the technical idea of the inventive concepts. Therefore, the inventive concepts are not limited to the above embodiments. Within the technical idea of the inventive concepts, various modifications and changes are possible, such as combining and implementing the above some embodiments by those skilled in the art.

What is claimed is:

1. A single photon detection device comprising:
a photodetection layer including a first surface and a second surface positioned on opposite sides;
wherein the photodetection layer comprises:
a first well having a first conductivity type;
backside patterns positioned between the second surface and the first well, having pitches smaller than a wavelength of light to be detected;
a heavily doped region positioned between the first surface and the first well, having a second conductivity type different from the first conductivity type; and
a contact region electrically connected to the first well and having the first conductivity type.

2. The single photon detection device of claim 1, wherein the backside patterns have a width that decreases along a direction from the second surface toward the first surface.

3. The single photon detection device of claim 1, wherein the photodetection layer further comprises a substrate region provided between the backside patterns and the first well, the substrate region including a semiconductor material.

4. The single photon detection device of claim 3, wherein the substrate region has concave portions into which the backside patterns are inserted, respectively.

5. The single photon detection device of claim 1, wherein the photodetection layer further comprises a backside reflection layer provided on the second surface,
wherein the backside reflection layer is configured to transmit light incident from the backside reflection layer to the photodetection layer and to reflect light incident from the photodetection layer to the backside reflection layer.

6. The single photon detection device of claim 1, wherein the photodetection layer further comprises a side reflection layer provided on a side surface of the first well.

7. The single photon detection device of claim 1, wherein the photodetection layer further comprises:
a first silicide layer provided on the first surface and covering the heavily doped region; and
a second silicide layer provided on the first surface, covering the contact region, and spaced apart from the first silicide layer.

8. The single photon detection device of claim 1, wherein the photodetection layer further comprises a guard ring surrounding the heavily doped region between the heavily doped region and the contact region, having the second conductivity type, and having a lower doping concentration than the heavily doped region.

9. The single photon detection device of claim 8, wherein the photodetection layer further comprises a second well provided between the heavily doped region and the first well, surrounded by the guard ring, and having the first conductivity type.

10. The single photon detection device of claim 8, wherein the photodetection layer further comprises a first silicide layer provided on the first surface and covering the heavily doped region and the guard ring.

11. The single photon detection device of claim 1, wherein the photodetection layer further comprises a lightly doped region provided between the first well and the heavily doped region, having the second conductivity type, and having a lower doping concentration than the heavily doped region.

12. The single photon detection device of claim 11, wherein the photodetection layer further comprises a guard ring surrounding the lightly doped region between the lightly doped region and the contact region, having the second conductivity type, and having a lower doping concentration than the lightly doped region.

13. The single photon detection device of claim 1, wherein the photodetection layer further comprises a device isolation pattern and a vertical isolation pattern sequentially arranged along a direction from the first surface to the second surface, provided adjacent to the first surface on a side surface of the first well.

14. The single photon detection device of claim 13, wherein the backside patterns are surrounded by the vertical isolation pattern.

15. The single photon detection device of claim 13, wherein the photodetection layer further comprises a side reflection layer extending from a region between the device isolation pattern and the contact region to a region between the vertical isolation pattern and the backside patterns.

16. The single photon detection device of claim 1, wherein the photodetection layer comprises a relaxation region provided between the contact region and the first well, having the first conductivity type, and having a lower doping concentration than the contact region.

17. The single photon detection device of claim 1, wherein the photodetection layer further comprises an insulation pattern provided between the heavily doped region and the contact region, the insulation pattern including an electrically insulating material.

18. The single photon detection device of claim 1, wherein the photodetection layer further comprises a second well provided between the heavily doped region and the first well and having the first conductivity type, and
wherein the heavily doped region protrudes from a side surface of the second well.

19. The single photon detection device of claim 1, further comprising:
a connection layer provided on the first surface, the connection layer including:
an output pattern electrically connected to the heavily doped region and configured to reflect light that has passed through the photodetection layer back to the photodetection layer, and
a bias pattern electrically connected to the contact region and configured to reflect light that has passed through the photodetection layer back to the photodetection layer.

20. The single photon detection device of claim 19, wherein, from a planar perspective, the heavily doped region entirely overlaps the output pattern.
